(19) United States
(12) Patent Application Publication
(10) Pub. No.: US 2021/0324169 A1
(43) Pub. Date: Oct. 21, 2021

(54) ENGINEERING A POROUS CONDUCTIVE PEDOT:PSS-DVS SCAFFOLD FOR MICROBIAL FUEL CELL AIR CATHODES

(71) Applicant: Northeastern University, Boston, MA (US)

(72) Inventors: Steven Lustig, Boston, MA (US); Devyesh Rana, Burlington, MA (US); Katchen Lachmayr, Reading, MA (US)

(21) Appl. No.: 17/222,116

(22) Filed: Apr. 5, 2021

Related U.S. Application Data
(60) Provisional application No. 63/004,633, filed on Apr. 3, 2020.

(51) Int. Cl. C08J 9/28; C08G 61/12; C08K 5/41; C08J 9/00; C08K 5/00

(52) U.S. Cl. CPC C08J 9/286; C08G 2101/00; C08K 5/41; C08J 9/0033; C08J 9/0023; C08K 5/0025; C08G 2261/3247; C08G 2261/135; C08J 2201/026; C08J 2365/00; C08J 2425/18; C08J 2201/0484; C08J 2205/044; C08K 2201/001; C08K 2201/011; C08G 2261/70; C08G 2261/90; C08G 61/126

(57) ABSTRACT

Disclosed are methods of making porous polymeric materials. Also provided herein are porous polymeric materials prepared by the disclosed methods.

### RELATED APPLICATIONS

This application claims the benefit of priority to U.S. Provisional Patent Application No. 63/004,633, filed Apr. 3, 2020.

### BACKGROUND

Conductive polymers provide a unique opportunity to combine traditional energetic materials with inexpensive components. The result is an unparalleled processability in which chemistries are tunable, and morphologies can be manipulated creating unique device architectures and applications. Traditional conductive materials utilized complex chemistries or expensive rare earth components. In contrast, organic chemistry-based derivatives provide further flexibility and tenability, which is more expensive to attain using conventional materials. Specifically, for air cathode materials, many conventional conductive materials utilized for the conductive layer are expensive and lack tunable morphologies.

### SUMMARY OF THE INVENTION

In certain aspects, provided herein are methods of making a cross-linked porous polymeric material, the method comprising:

inducing porosity and cross-linking in a mixture comprising PEDOT, an additional polymer, a cross-linker, and at least one solvent to form a cross-linked porous polymeric material;

wherein:

the cross-linked porous polymeric material comprises a plurality of pores having an average pore diameter;

the additional polymer is an acidic polymer, a basic polymer, a polyanionic polymer, a polycationic polymer, a sulfonate-containing polymer, a biopolymer, or an amphoteric polymer; and

the cross-linker is a molecule with two or more vinyl functional groups, a metal oxide, a metal hydrate, or a combination thereof.

In further aspects, provided herein are methods of making a cross-linked porous polymeric material, the method comprising:

inducing porosity and cross-linking in a mixture comprising PEDOT, an additional polymer, a cross-linker, and at least one solvent;

wherein the induction of porosity and cross-linking comprises one or more steps selected from the group consisting of:

1) solvent-non-solvent interactions between the at least one solvent and a non-solvent;

2) cooling at a cooling rate to a sub-freezing temperature that is below the freezing point of the at least one solvent;

3) adding nanoparticle fillers having an average nanoparticle diameter and subsequent removal of the nanoparticle fillers; and

4) adding an additional solvent, wherein the additional solvent has a melting point which is higher than about 25° C. to form a high melting mixture, foaming the high melting mixture to form a foamed mixture, and optionally subliming or melting the foamed mixture;

thereby forming a cross-linked porous polymeric material;

wherein:

the cross-linked porous polymeric material comprises a plurality of pores having an average pore diameter;

the additional polymer is an acidic polymer, a basic polymer, a polyanionic polymer, a polycationic polymer, a sulfonate-containing polymer, a biopolymer, or an amphoteric polymer; and

the cross-linker is a molecule with two or more vinyl functional groups, a metal oxide, a metal hydrate, or a combination thereof.

In yet further aspects, provided herein are methods of making a porous polymeric material, the method comprising:

admixing PEDOT and an additional polymer with a first solvent to form a dispersed polymer mixture;

combining the dispersed polymer mixture and a cross-linker or a cross-linker solution to form a combined mixture; wherein the cross-linker solution comprises the cross-linker and a second solvent;

applying the combined mixture to a surface or vessel;

inducing cross-linking and porosity in the combined mixture to form a porous polymeric material comprising a cross-linked polymer, wherein the porous polymeric material comprises a plurality of pores having an average pore diameter;

wherein:

the additional polymer is selected from the group consisting of an acidic polymer, a basic polymer, a polyanionic polymer, a sulfonate-containing polymer, a biopolymer, and an amphoteric polymer; and

the cross-linker is selected from the group consisting of a molecule with two or more vinyl functional groups, a metal oxide, and a metal hydrate, or a combination thereof.

In still further aspects, provided herein are porous polymeric materials, including but not limited to thin films, sponges, foams, wafers, sheets, fibers, and gels, made by the methods disclosed herein.

### BRIEF DESCRIPTION OF THE DRAWINGS

FIG. 1A depicts an SEM image of the top view of a porous PEDOT:PSS-DVS (150 mM PEDOT:PSS and 85 mM DVS) material prepared using sub-freezing cross-linking as described in Example 18.

FIG. 1B depicts an SEM image of the cross-section of a porous PEDOT:PSS-DVS (150 mM PEDOT:PSS and 85 mM DVS) material prepared using sub-freezing cross-linking as described in Example 18.

FIG. 2A depicts an SEM images of the top view of a porous PEDOT:PSS-DVS (150 mM PEDOT:PSS and 85 mM DVS) material prepared using phase separation as described in Example 19 with water as the solvent and toluene as the non-solvent.

FIG. 2B depicts an SEM images of the cross-section of a porous PEDOT:PSS-DVS (150 mM PEDOT:PSS and 85 mM DVS) material prepared using phase separation as described in Example 19 with water as the solvent and toluene as the non-solvent.

FIG. 2C depicts an SEM images of the top view of a porous PEDOT:PSS-DVS (150 mM PEDOT:PSS and 85 mM DVS) material prepared using phase separation as described in Example 19 with water as the solvent and chloroform as the non-solvent.

FIG. 2D depicts an SEM images of the cross-section of a porous PEDOT:PSS-DVS (150 mM PEDOT:PSS and 85 mM DVS) material prepared using phase separation as described in Example 19 with water as the solvent and chloroform as the non-solvent.

FIG. 2E depicts an SEM images of the top view of a porous PEDOT:PSS-DVS (150 mM PEDOT:PSS and 85 mM DVS) material prepared using phase separation as described in Example 19 with water as the solvent and nitrobenzene as the non-solvent.

FIG. 2F depicts an SEM images of the cross-section of a porous PEDOT:PSS-DVS (150 mM PEDOT:PSS and 85 mM DVS) material prepared using phase separation as described in Example 19 with water as the solvent and nitrobenzene as the non-solvent.

FIG. 3A depicts an SEM image of the top view of a porous PEDOT:PSS-DVS (150 mM PEDOT:PSS and 85 mM DVS) material prepared using Phase Inversion Foaming, with camphene as the solvent, as described in Example 21.

FIG. 3B depicts an SEM image of the cross-section of a porous PEDOT:PSS-DVS (150 mM PEDOT:PSS and 85 mM DVS) material prepared using phase inversion foaming, with camphene as the solvent, as described in Example 21.

FIG. 4A depicts an SEM image of a porous PEDOT:PSS-DVS (25 mM PEDOT:PSS and 0.03 mM DVS) material prepared using sub-freezing cross-linking as described in Example 18.

FIG. 4B depicts an SEM image of a porous PEDOT:PSS-DVS (50 mM PEDOT:PSS and 0.03 mM DVS) material prepared using sub-freezing cross-linking as described in Example 18.

FIG. 4C depicts a histogram of pore size of porous PEDOT:PSS-DVS (12.5, 25, and 50 mM PEDOT:PSS and 0.03 mM DVS) material prepared using sub-freezing cross-linking as described in Example 18.

FIG. 5A depicts an SEM image of a porous PEDOT:PSS-DVS (25 mM PEDOT:PSS and 0.03 mM DVS) material prepared using phase inversion foaming, with camphene as the solvent, as described in Example 21.

FIG. 5B depicts an SEM image of a PEDOT:PSS-DVS (25 mM PEDOT:PSS and 0.03 mM DVS) material prepared using phase inversion foaming, with camphene as the solvent, as described in Example 21.

FIG. 5C depicts a histogram of pore size of PEDOT:PSS-DVS (12.5, 25, and 50 mM PEDOT:PSS and 0.03 mM DVS) material prepared using phase inversion foaming, with camphene as the solvent, as described in Example 21.

FIG. 6A depicts an SEM image of a porous PEDOT:PSS-DVS (12.5 mM PEDOT:PSS and 0.03 mM DVS) prepared using phase separation as described in Example 19 with water as the solvent, γ-butyrolactone as the non-solvent, and Triton X as the surfactant, with a ratio of 80:8:10:2 ([PEDOT:PSS]:DVS:γ-butyrolactone:TritonX).

FIG. 6B depicts an SEM image of a porous PEDOT:PSS-DVS (25 mM PEDOT:PSS and 0.03 mM DVS) prepared using phase separation as described in Example 19 with water as the solvent, γ-butyrolactone as the non-solvent, and Triton X as the surfactant, with a ratio of 80:8:10:2 ([PEDOT:PSS]:DVS:γ-butyrolactone:TritonX).

FIG. 6C depicts an SEM image of a porous PEDOT:PSS-DVS (50 mM PEDOT:PSS and 0.03 mM DVS) prepared using phase separation as described in Example 19 with water as the solvent, γ-butyrolactone as the non-solvent, and Triton X as the surfactant, with a ratio of 80:8:10:2 ([PEDOT:PSS]:DVS:γ-butyrolactone:TritonX).

FIG. 6D depicts a histogram of pore size of porous PEDOT:PSS-DVS (12.5, 25, and 50 mM PEDOT:PSS and 0.03 mM DVS) prepared using phase separation as described in Example 19 with water as the solvent, γ-butyrolactone as the non-solvent, and Triton X as the surfactant, with a ratio of 80:8:10:2 ([PEDOT:PSS]:DVS:γ-butyrolactone:TritonX).

FIG. 7A depicts an SEM image of a porous PEDOT:PSS-DVS (12.5 mM PEDOT:PSS and 0.03 mM DVS) prepared using phase separation as described in Example 19 with water as the solvent, toluene as the non-solvent, and Triton X as the surfactant, with a ratio of 80:8:10:2 ([PEDOT:PSS]:DVS:Toluene:TritonX).

FIG. 7B depicts an SEM image of a porous PEDOT:PSS-DVS (25 mM PEDOT:PSS and 0.03 mM DVS) prepared using phase separation as described in Example 19 with water as the solvent, toluene as the non-solvent, and Triton X as the surfactant, with a ratio of 80:8:10:2 ([PEDOT:PSS]:DVS:Toluene:TritonX).

FIG. 7C depicts an SEM image of a porous PEDOT:PSS-DVS (50 mM PEDOT:PSS and 0.03 mM DVS) prepared using phase separation as described in Example 19 with water as the solvent, toluene as the non-solvent, and Triton X as the surfactant, with a ratio of 80:8:10:2 ([PEDOT:PSS]:DVS:Toluene:TritonX).

FIG. 7D depicts a histogram of pore size of porous PEDOT:PSS-DVS (12.5, 25, and 50 mM PEDOT:PSS and 0.03 mM DVS) prepared using phase separation as described in Example 19 with water as the solvent, toluene as the non-solvent, and Triton X as the surfactant, with a ratio of 80:8:10:2 ([PEDOT:PSS]:DVS:Toluene:TritonX).

FIG. 8A depicts an optical microscopy image of PEG nanoparticles (1 mmol) in PEDOT:PSS-DVS (25 mM PEDOT:PSS and 0.03 mM DVS) solution, as described in Example 22.

FIG. 8B depicts an optical microscopy image of PEG nanoparticles (2 mmol) in PEDOT:PSS-DVS (25 mM PEDOT:PSS and 0.03 mM DVS) solution, as described in Example 22.

FIG. 8C depicts an optical microscopy image of PEG nanoparticles (3 mmol) in PEDOT:PSS-DVS (25 mM PEDOT:PSS and 0.03 mM DVS) solution, as described in Example 22.

FIG. 8D depicts an optical microscopy image of PEG nanoparticles (4 mmol) in PEDOT:PSS-DVS (25 mM PEDOT:PSS and 0.03 mM DVS) solution, as described in Example 22.

FIG. 8E depicts an optical microscopy image of PEG nanoparticles (5 mmol) in PEDOT:PSS-DVS (25 mM PEDOT:PSS and 0.03 mM DVS) solution, as described in Example 22.

FIG. 8F depicts an optical microscopy image of PEG nanoparticles (6 mmol) in PEDOT:PSS-DVS (25 mM PEDOT:PSS and 0.03 mM DVS) solution, as described in Example 22.

FIG. 8G depicts an optical microscopy image of PEG nanoparticles (8 mmol) in PEDOT:PSS-DVS (25 mM PEDOT:PSS and 0.03 mM DVS) solution, as described in Example 22.

FIG. 8H depicts an optical microscopy image of PEG nanoparticles (10 mmol) in PEDOT:PSS-DVS (25 mM PEDOT:PSS and 0.03 mM DVS) solution, as described in Example 22.

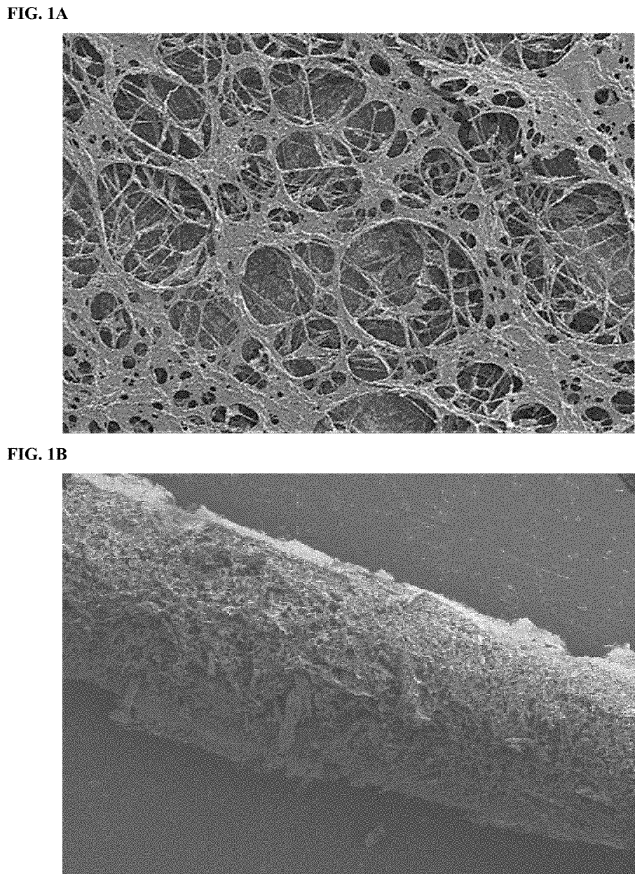

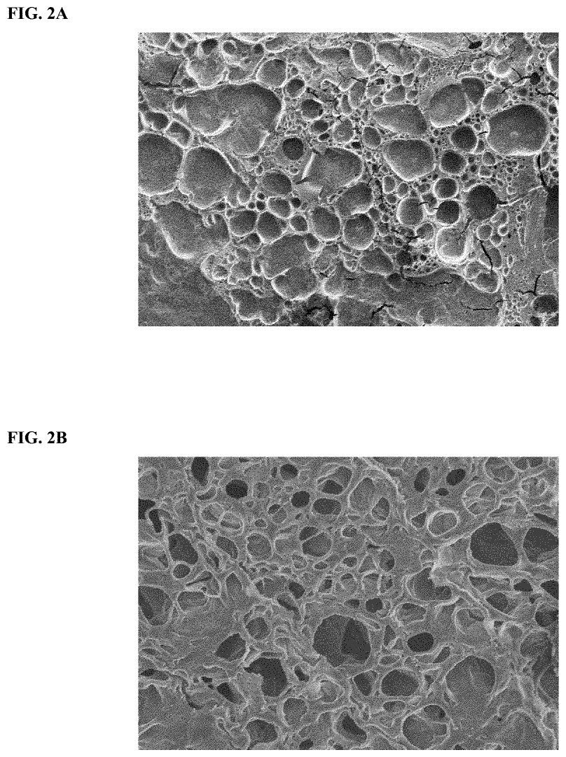

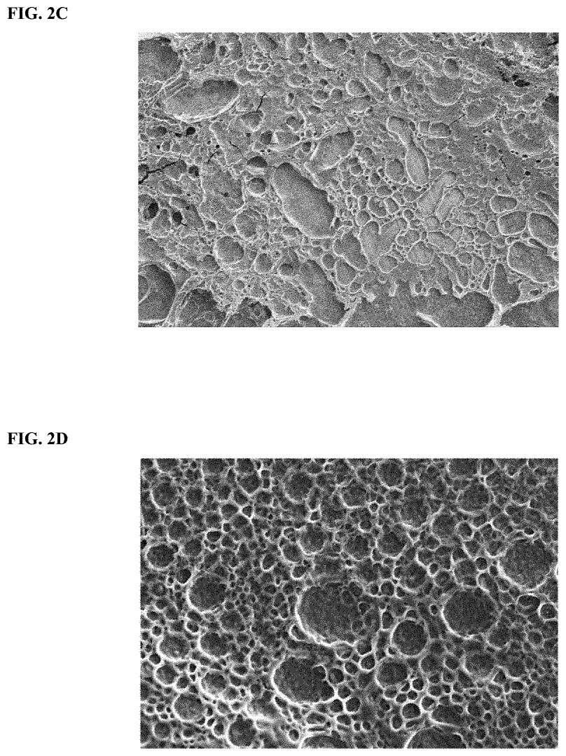

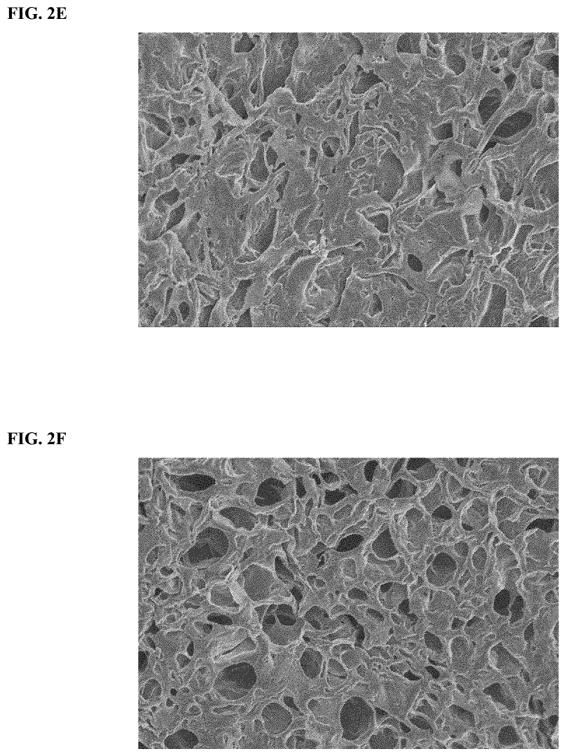

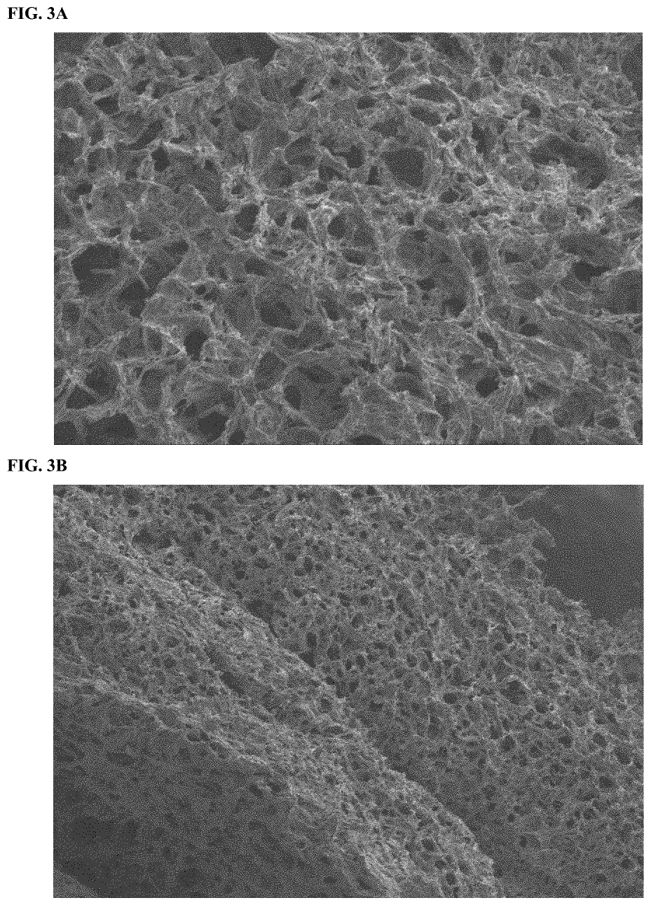

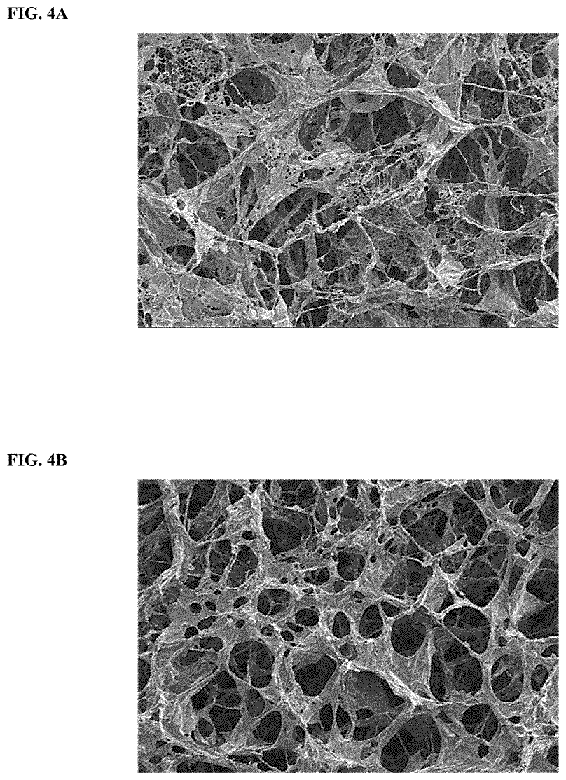

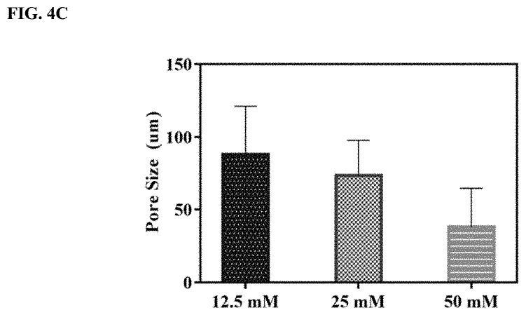

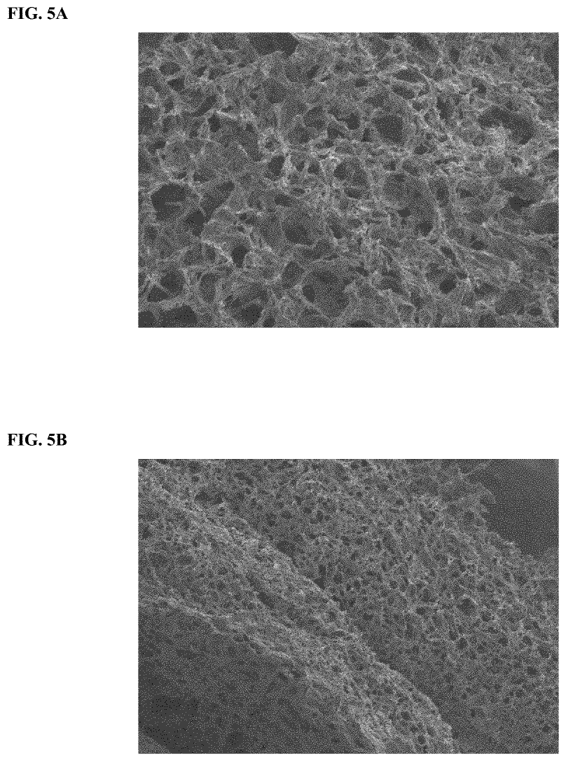

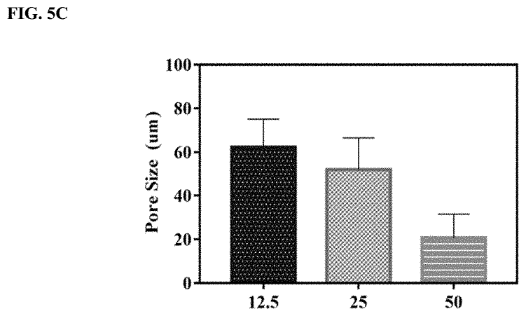

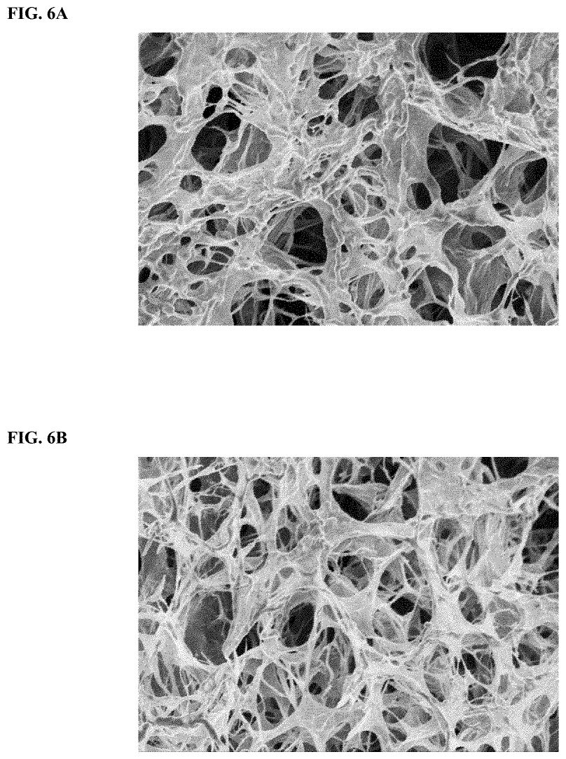

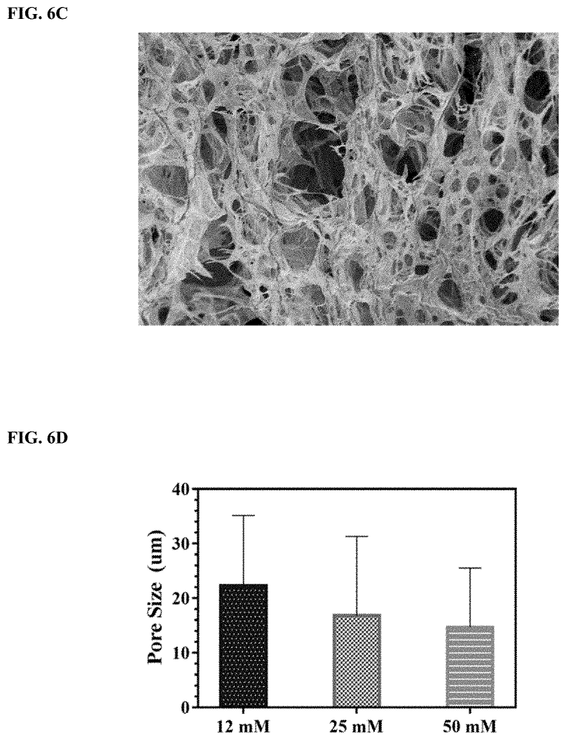

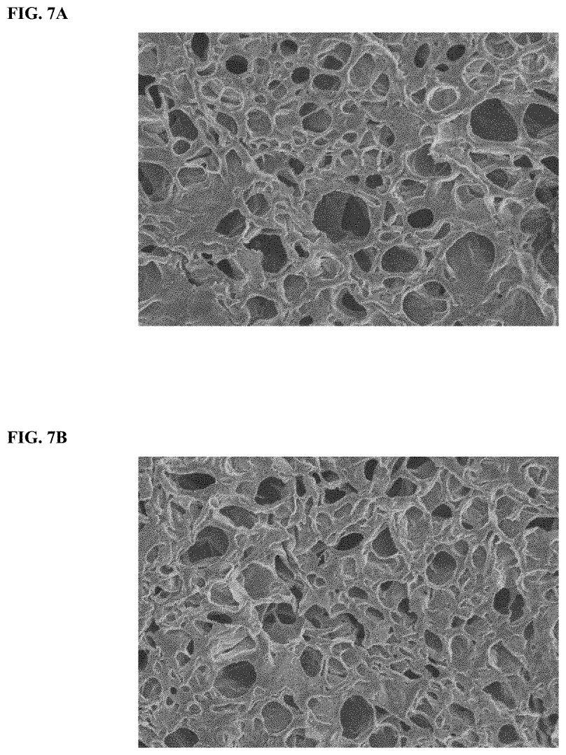

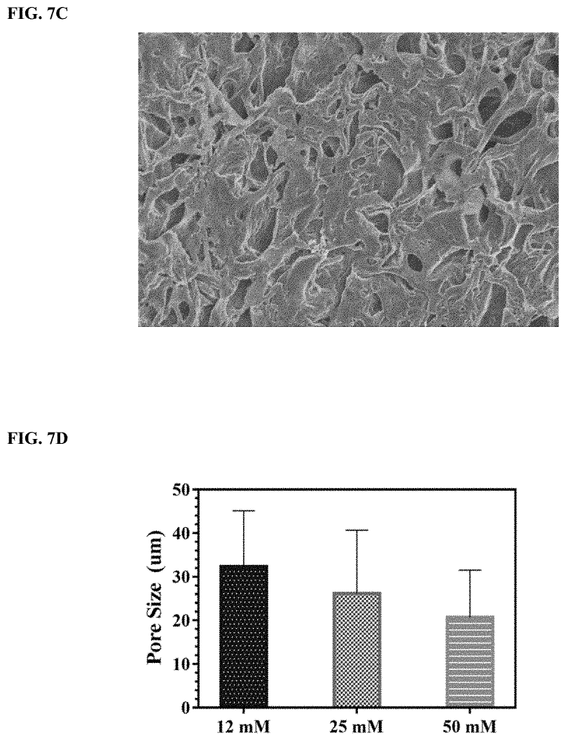

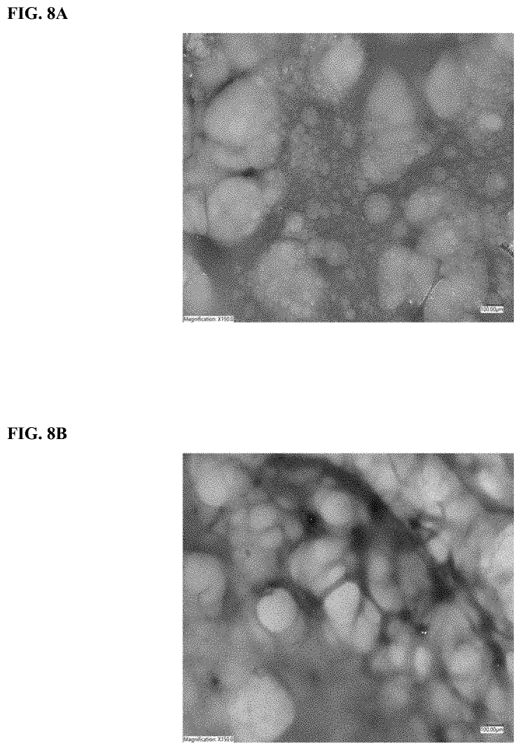

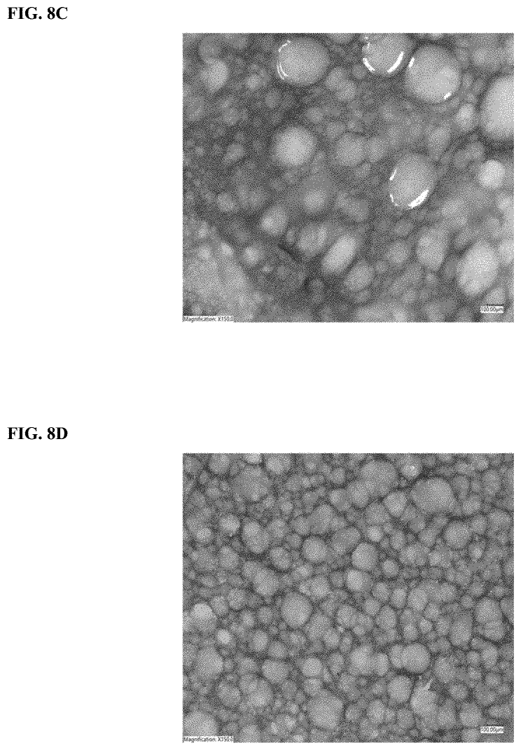

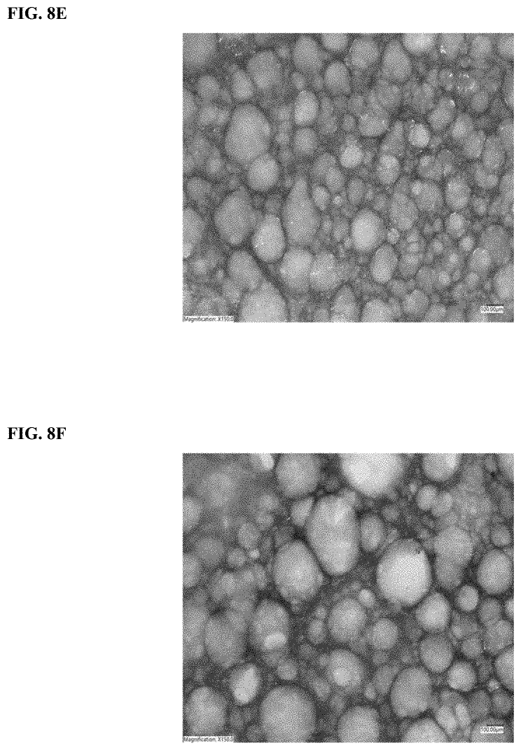

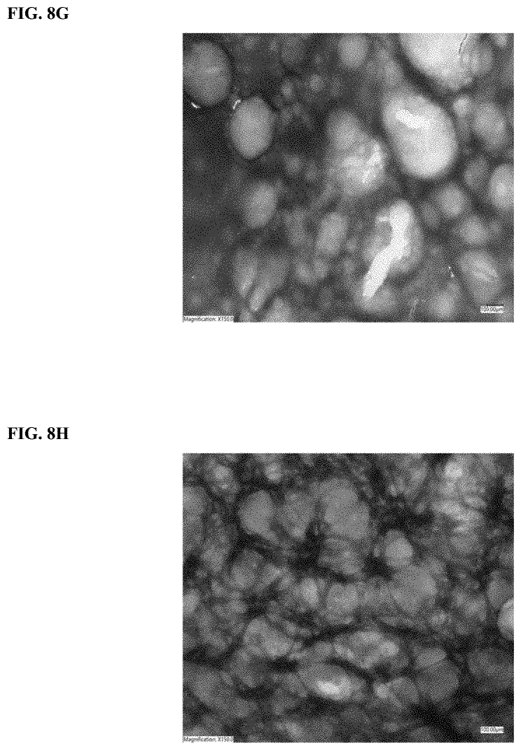

### DETAILED DESCRIPTION OF THE INVENTION

Poly(3,4-ethylenedioxythiophene)-poly(styrenesulfonate) (PEDOT:PSS) is a polymer which has received attention as a unique conductive electrode material; however, very little in the way of morphological tunability has been attained. This is due in part to the quick redispersing properties of PEDOT:PSS in solution. Therefore interest has extended to PEDOT:PSS morphological attributes with and without crosslinkers. Creating PEDOT:PSS aerogels using liquid nitrogen (−200° C. approximately) has been investigated. Additionally, PEDOT:PSS has been crosslinked with 3-glycidoxypropyltrimethoxysilane (GOPS) and divinyl sulfone (DVS) followed by ice templating at −80° C.

Alternative approaches utilize Fe(NO₃)₃.9H₂O and crosslinkers such as iron (Fe³⁺); however, these ions cannot be completely removed and induce new scattering centers which can lower efficiencies and conductivity. Finally, other approaches include the mixing and complexing of PEDOT:PSS with other substances. Additionally, annealing of PEDOT:PSS at elevated temperature has been shown to enable recrystallization of PEDOT-rich nanofibrils and chain rearrangement for both PEDOT and PSS, which induces formation of a crosslinked material. The present disclosure described a technology where PEDOT:PSS can be made to possess tunable porosity with or without crosslinking and with or without annealing. Specifically, multiple techniques which can achieve porosity within the PEDOT:PSS framework can be employed.

Technique 1 employs phase separation using solvent-nonsolvent interactions to force porosity.

Technique 2 employs sub-freezing crosslinking which includes room temperature (sub-freezing for the solvent) crosslinking to generate porosity. The porosity can be tuned by controlling rate of freezing and/or freezing temperature.

Technique 3 employs nanoparticle loading (filler chemistry) which can then be melted, evaporated, or sublimated out of the end polymer network. Pore size can be controlled by changing the diameter of the nanoparticles used.

Technique 4 employs foaming technologies in which PEDOT:PSS is dispersed in a solvent with a higher melting point than room temperature. The solid PEDOT:PSS-solvent mixture, depending on the solvent, can be sublimed at room temperature or processed further to induce porosity.

Technique 5 employs metal crosslinkers: silver oxides and hydrates, gold oxides and hydrates, aluminum oxides and hydrates, zinc oxides and hydrates, copper oxides and hydrates, magnesium oxides and hydrates, calcium oxides and hydrates, iron oxides and hydrates, and chromium oxides and hydrates.

The problem at hand is the period replacement of an air cathode within microbial fuel cells. The cathode is comprised of a conductive component (electron transfer), a catalyst (reaction mechanism), and an air diffusion component (oxygen transfer). In prior art the entire air cathode assembly must be replaced, regardless of the fact that the conductive component is expensive. The present disclosure relates in some embodiments to an inexpensive on-demand deployment (spray) of the conductive component (for example paint). The PEDOT:PSS-DVS can be sprayed and crosslinked anywhere. Furthermore, extensive chemical analysis has been conducted which proves the chemistry proposed herein. Additionally, the PEDOT:PSS-DVS has a porous structure which can be loaded with catalyst or other nanoparticles/substances or left unloaded for diffusion of media.

In some embodiments, the present disclosure relates to materials which can serve as conductive layer in the air cathode of a microbial fuel cell. However, due to this novel deployment method of applying a conductive spray material, this can also be applied to a number of other applications, including solar cells, fibers, and conductive patches.

The technology of the present disclosure is more cost-effective because the raw components are less expensive than currently used components (carbon, platinum, etc.) and require less processing. Moreover, because of the porous microstructure, there is less raw material being consumed to make an equally efficient product.

The technology of the present disclosure provides a more efficient and user friendly approach to periodic cathode replacements. This, in turn drives down costs because it does not require to be manufactured elsewhere. The end user applies the spray on PEDOT:PSS-DVS at home upon catalyst acquisition.

A commercial application for the disclosed technology is in the fuel cell space, specifically microbial fuel cells. Currently, the technology requires expensive components which need to be periodically replaced, based on catalyst.

A commercial application for the disclosed technology includes solar cells, conductive patches, and other electronics which has a much higher market potential.

### Definitions

Listed below are definitions of various terms used herein. These definitions apply to the terms as they are used throughout this specification and claims, unless otherwise limited in specific instances, either individually or as part of a larger group.

Unless defined otherwise, all technical and scientific terms used herein generally have the same meaning as commonly understood by one of ordinary skill in the art to which this invention belongs. Generally, the nomenclature used herein and the laboratory procedures in chemistry and engineering are those well-known and commonly employed in the art.

As used herein, the articles “a” and “an” refer to one or to more than one (i.e., to at least one) of the grammatical object of the article. By way of example, “an element” means one element or more than one element. Furthermore, use of the term “including” as well as other forms, such as “include,” “includes,” and “included,” is not limiting.

As used herein, the term “about” will be understood by persons of ordinary skill in the art and will vary to some extent on the context in which it is used. As used herein when referring to a measurable value such as an amount, a temporal duration, and the like, the term “about” is meant to encompass variations of ±5%, from the specified value, as such variations are appropriate to perform the disclosed methods.

As used in the specification and in the claims, the term “comprising” may include the embodiments “consisting of” and “consisting essentially of” The terms “comprise(s),” “include(s),” “having,” “has,” “may,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated compounds, which allows the presence of only the named compounds, along with any pharmaceutically acceptable carriers, and excludes other compounds.

All ranges disclosed herein are inclusive of the recited endpoint and independently combinable (for example, the range of “from 50 mg to 500 mg” is inclusive of the endpoints, 50 mg and 500 mg, and all the intermediate values). The endpoints of the ranges and any values disclosed herein are not limited to the precise range or value; they are sufficiently imprecise to include values approximating these ranges and/or values.

As used herein, the terms “weight percent,” “wt %,” or “% w/w” are meant to refer to the quantity by weight of a compound and/or component in a composition as the quantity by weight of a constituent component of the composition as a percentage of the weight of the total composition. The weight percent can also be calculated by multiplying the mass fraction by 100. The “mass fraction” is the ratio of one substance of a mass mi to the mass of the total composition MT such that weight percent=(m₁/m_{T})*100.

As used herein, the terms “volume percent,” “vol %,” or “% v/v” are meant to refer to the quantity by volume of a compound and/or component in a composition as the quantity by volume of a constituent component of the composition as a percentage of the volume of the total composition.

### Methods of Making

In certain aspects, provided herein are methods of making a cross-linked porous polymeric material, the method comprising:

inducing porosity and cross-linking in a mixture comprising PEDOT, an additional polymer, a cross-linker, and at least one solvent to form a cross-linked porous polymeric material;

wherein:

the cross-linked porous polymeric material comprises a plurality of pores having an average pore diameter;

the additional polymer is an acidic polymer, a basic polymer, a polyanionic polymer, a polycationic polymer, a sulfonate-containing polymer, a biopolymer, or an amphoteric polymer; and

the cross-linker is a molecule with two or more vinyl functional groups, a metal oxide, a metal hydrate, or a combination thereof.

In certain embodiments, the additional polymer is selected from the group consisting of PSS, Poly(acrylamide), Poly(N-isopropyl acrylamide), Poly(N-octyl acrylamide), Poly(N-tert-butyl acrylamide), Poly(N-phenyl acrylamide), Poly(N-sec-butyl acrylamide), Poly(acrylic acid), Poly(benzyl acrylate), Poly(butyl acrylate), Poly(4-chlorophenyl acrylate), Poly(-cyanoethyl acrylate), Poly(cyanomethyl acrylate), Poly(cyclohexyl acrylate), Poly(ethyl acrylate), Poly(2-ethylhexyl acrylate), Poly(hexyl acrylate), Poly(isobutyl acrylate), Poly(isopropyl acrylate), Poly(methyl acrylate), Poly(octyl acrylate), Poly(propyl acrylate), Poly(sec-butyl acrylate), Poly(stearyl acrylate), Poly(tert-butyl acrylate), Poly(2,2,3,3-Tetrafluoropropyl acrylate), Poly(acrylonitrile), Poly(methacrylonitrile), Poly(butylene adipate), Poly(ethylene adipate), Poly(propylene adipate), Poly(butylene), Poly(butyl ethylene), Poly(cyclohexylethylene), Poly(ethylene), Poly(heptylethylene), Poly(hexylethylene), Poly(isobutene), Poly(isobutylethylene), Poly(isopropylethylene), Poly(2-methylbutene), Poly(octylethylene), Poly(pentylethylene), Poly(propylene), Poly(propylethylene), Poly(tert-butylethylene), Nylon 3-Poly(propiolactam), Nylon 6-Poly(caprolactam), Nylon 8-Polycapryllactam, Nylon 10-Poly(decano-10-lactam), Nylon 11-Poly(undecano-11-lactam), Nylon 12-Poly(dodecano-12-lactam), Nylon 4,6-Poly(tetramethylene adipamide), Nylon 6,6-Poly(hexamethylene adipamide), Nylon 6,9-Poly(hexamethylene azelamide), Nylon 6,10-Poly(hexamethylene sebacamide), Nylon 6,12-Poly(hexamethylene dodecanediamide), Nylon 10,10 -Poly(decamethylene sebacamide), Poly(hexamethylene isophthalamide), Poly(hexamethylene teraphthalamide), Kevlar-Polyaramide, Nomex-Poly(m-phenylene terephthalamide), Poly(nonanmethylene teraphthalamide), Poly(p-pentamethylenedibenzoic anhydride), Poly(p-tetramethylenedibenzoic anhydride), Poly(sebacic anhydride), Poly(azelaic anhydride), Poly(1,2-butadiene), Poly(1,4-butadiene), Polycyclopentene, Poly(1-ethyl-1,4-butadiene), 1,4-Polyisoprene (cis and trans), Poly(1,4-pentadiene), Poly(1-pentenylene), Poly(dimethyl fumarate), Poly(dibutyl fumarate), Poly(diethyl fumarate), Poly(dipropyl fumarate), Poly(bisphenol A carbonate), Poly(4,4′-thiodiphenylene carbonate), Poly(bisphenol B carbonate), Poly(bisphenol F carbonate), Poly(ethylene carbonate), Poly(propylene carbonate), Poly(2,6,3′,5′-tetrachloro bisphenol A carbonate), Poly(tetramethyl bisphenol A carbonate), Cellulose Acetate, Methyl Cellulose, Ethyl Cellulose, Poly(chlorotrifluoroethylene), Poly(tetrafluoroethylene), Poly(vinyl bromide), Poly(vinyl chloride), Poly(vinyl fluoride), Poly(vinylidene chloride), Poly(vinylidene fluoride), Poly(methyl cyanoacrylate), Poly(ethyl cyanoacrylate), Poly(butyl cyanoacrylate), Poly(hexyl cyanoacrylate), Poly(octyl cyanoacrylate), Poly(1,2-butadiene), Poly(1,4-butadiene), Poly(1-pentenylene), Bisphenol-A diglycidyl ether epoxy resin, Bisphenol-F diglycidyl ether epoxy resin, Poly(bis-A diglycidyl ether-alt-ethylenediamine), Poly(bis-A diglycidyl ether-alt-hexamethylenediamine), Poly(bis-A diglycidyl ether-alt-octamethylenediamine), Poly(Bisphenol A isophthalate), Poly(Bisphenol A terephthalate), Poly(butylene isophthalate), Poly(butylene sebacate), Poly(butylene succinate), Poly(butylene terephthalate), Poly(ethylene sebacate), Poly(ethylene succinate), Poly(caprolactone), Poly(cyclohexylenedimethylene terephthalate), Poly(ethylene isophthalate), Poly(ethylene naphthalate), Poly(ethylene phthalate), Poly(ethylene terephthalate), Polyglycolide, Poly(hexylene sebacate), Poly(hexylene succinate), Poly(3-hydroxybutyrate), Poly(4-hydroxybutyrate), Polylactic acid, Poly(trimethylene succinate), Poly(trimethylene terephthalate), Polyacetal-Polyoxymethylene, Poly(3-butoxypropylene oxide), Poly(epichlorohydrin), Poly(ethylene glycol), Poly(hexamethylene oxide), Poly(3-methoxypropylene oxide), Poly[oxy(hexyloxymethyl)ethylene], Poly(oxymethylene-oxyethylene), Poly(oxymethylene-oxytetramethylene), Poly(propylene glycol), Poly(tetrahydrofuran), Poly(trimethylene glycol), Poly[1,1-bis(chloromethyl)trimethylene oxide], PEK-Poly(ether ketone), PEKK-Poly(ether ketone ketone), PEEK-Poly(ether ether ketone), Poly(ethyleneketone), Poly(propyleneketone), Poly(ether ether sulfone), Poly(ethersulfone), Poly(phenylsulfone), Bisphenol A Polysulfone, PoIy(1-chloro-1-butenylene) (Polychloroprene), Poly(1-bromo-1-butenylene) (Polybromoprene), Poly(4-bromostyrene), Poly(2-chlorostyrene), Poly(3-chlorostyrene), Poly(4-chlorostyrene), Poly(2,5-difluorostyrene), Poly(4-fluorostyrene), Poly(2-hydroxyethyl acrylate), Poly(2-hydroxyethyl methacrylate), Poly(2-hydroxypropyl methacrylate), Poly[(diethylene glycol)-alt-(1,6-hexamethylene diisocyanate)], Poly[(tetraethylene glycol)-alt-(1,6-hexamethylene diisocyanate)], Poly[(1,4-butanediol)-alt-(4,4′-diphenylmethane diisocyanate)], Poly[(ethylene glycol)-alt-(4,4′-diphenylmethane diisocyanate)], Poly[(polytetrahydrofuran 1000)-alt-(4,4′-diphenylmethane diisocyanate)], Poly(1,2-butadiene), Poly(1-pentenylene), Poly[dimethyl itaconate], Poly[di(n-propyl) itaconate], Poly[di(n-butyl) itaconate], Poly[di(n-hexyl) itaconate], Poly(p-phenylene), Poly(p-phenylene vinylene), Poly(p-xylene), Poly(2-chloro-p-xylylene), Poly(2,6-dimethyl-p-phenylene oxide), Poly(2,6-diphenyl-p-phenylene oxide), Poly(p-phenylene oxide), Poly(thio-1,4-phenylene), Poly(ethylene sulfide), Poly(propylene sulfide), Poly(vinyl alcohol), Poly(4-vinyl phenol), Poly(vinyl butyral), Poly(vinyl formal), Poly(vinyl acetate), Poly(vinyl benzoate), Poly(vinyl butyrate), Poly(vinyl caproate), Poly(vinyl formate), Poly(vinyl propionate), Poly(vinyl stearate), Poly(vinyl valerate), Poly(vinyl ethyl ketone), Poly(vinyl methyl ketone), Poly(methyl isopropenyl ketone), Poly(vinyl phenyl ketone), Poly(vinyl pyrrolidone), Poly(vinyl butyl sulfide), Poly(vinyl ethyl sulfide), Poly(vinyl methyl sulfide), Poly(vinyl phenyl sulfide), or Poly(vinyl propyl sulfide), Polysaccharides, such as cellulose, starch, glycogen, chitin, chitosan, pectin, callose, inulin, galactogen, amylose, amylopectin, chrysolaminarin, xylan, arabinoxylan, fucoidan, guar gum, and biopolymers such as alginate and collagen. In preferred embodiments, the additional polymer is PSS.

In certain embodiments, the cross-linker is a molecule with two or more vinyl functional groups. In further embodiments, the molecule with two or more vinyl functional groups is selected from the group consisting of DVS, 1,4-Bis(4-vinylphenoxy)butane, divinylbenzene, p-divinylbenzene, 4-Vinylbenzocyclobutene, Divinyl sulfone, 3,9-Divinyl-2,4,8,10-tetraoxaspiro[5.5]undecane, Divinyl sulfoxide, 1,4-Butanediol divinyl ether, 1,4-Cyclohexanedimethanol divinyl ether, 1,3-divinyl-1,1,3,3-tetramethyldisiloxane, Platinum(0)-1,3-divinyl-1,1,3,3-tetramethyldisiloxane, Di(ethylene glycol) divinyl ether, Poly(dimethylsiloxane-co-diphenylsiloxane) divinyl terminated, Poly(ethylene glycol) divinyl ether, Tri(ethylene glycol) divinyl Ether, 1,4-Pentadien-3-ol, Vinyl Acrylate, Protoporphyrin IX Dimethyl Ester, Protoporphyrin IX Zinc(II), 1,3-divinyl-5-isobutyl-5-methylhydantoin, 1,4-divinyl-1,1,2,2,3,3,4,4-octamethyltetrasilane, 3,6-divinyl-2-methyltetrahydropyran, Poly(Dimethylsiloxane), vinyl terminated, [1,3-Bis(2,6-diisopropylphenyl)-imidazolidinylidene][1,3-divinyl-1,1,3,3-tetramethyldisiloxane]platinum(0), [1,3-Bis(cyclohexyl)imidazol-2-ylidene][1,3-divinyl-1,1,3,3-tetramethyldisiloxane]platinum(0), 3,7,12,17-Tetramethyl-8,13-divinyl-2,18-porphinedipropionic acid, Kammerer's porphyrin, 3,7,12,17-Tetramethyl-8,13-divinyl-2,18-porphinedipropionic acid, [1,3-Bis(2,6-diisopropylphenyl)imidazol-2-ylidene][1,3-divinyl-1,1,3,3-tetramethyldisiloxane]platinum(0), Vinylboronic anhydride, 1,2,4-Trivinylcyclohexane, or butadiene. In preferred embodiments, the molecule with two or more vinyl functional groups is DVS.

In certain embodiments, the cross-linker is a metal oxide. In further embodiments, the metal oxide is selected from the group consisting of silver oxide, gold oxide, aluminum oxide, zinc oxide, copper oxide, magnesium oxide, calcium oxide, lithium oxide, iron oxide, chromium oxide, and titanium oxide.

In certain embodiments, the cross-linker is a metal hydrate. In further embodiments, the metal hydrate is selected from the group consisting of silver hydrate, gold hydrate, aluminum hydrate, zinc hydrate, copper hydrate, magnesium hydrate, calcium hydroxide, iron hydrate, and chromium (III) sulfate hydrate.

In certain embodiments, the at least one solvent is selected from the group consisting of water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the at least one solvent is water.

In certain embodiments, the concentration of the PEDOT and the additional polymer in the at least one solvent is about 0.5% w/w to about 10% w/w. In further embodiments, the concentration of the PEDOT and the additional polymer in the at least one solvent is about 0.5% w/w. In yet further embodiments, the concentration of the PEDOT and the additional polymer in the at least one solvent is about 0.6% w/w. In still further embodiments, the concentration of the PEDOT and the additional polymer in the at least one solvent is about 0.7% w/w. In certain embodiments, the concentration of the PEDOT and the additional polymer in the at least one solvent is about 0.8% w/w. In further embodiments, the concentration of the PEDOT and the additional polymer in the at least one solvent is about 0.9% w/w.

In certain embodiments, the concentration of the PEDOT and the additional polymer in the at least one solvent is about 1% w/w. In further embodiments, the concentration of the PEDOT and the additional polymer in the at least one solvent is about 1.5% w/w. In yet further embodiments, the concentration of the PEDOT and the additional polymer in the at least one solvent is about 2% w/w. In still further embodiments, the concentration of the PEDOT and the additional polymer in the at least one solvent is about 2.5% w/w.

In certain embodiments, the concentration of the PEDOT and the additional polymer in the at least one solvent is about 3% w/w. In further embodiments, the concentration of the PEDOT and the additional polymer in the at least one solvent is about 3.5% w/w. In yet further embodiments, the concentration of the PEDOT and the additional polymer in the at least one solvent is about 4% w/w. In still further embodiments, the concentration of the PEDOT and the additional polymer in the at least one solvent is about 4.5% w/w.

In certain embodiments, the concentration of the PEDOT and the additional polymer in the at least one solvent is about 5% w/w. In further embodiments, the concentration of the PEDOT and the additional polymer in the at least one solvent is about 5.5% w/w. In yet further embodiments, the concentration of the PEDOT and the additional polymer in the at least one solvent is about 6% w/w. In still further embodiments, the concentration of the PEDOT and the additional polymer in the at least one solvent is about 6.5% w/w.

In certain embodiments, the concentration of the PEDOT and the additional polymer in the at least one solvent is about 7% w/w. In further embodiments, the concentration of the PEDOT and the additional polymer in the at least one solvent is about 7.5% w/w. In yet further embodiments, the concentration of the PEDOT and the additional polymer in the at least one solvent is about 8% w/w. In still further embodiments, the concentration of the PEDOT and the additional polymer in the at least one solvent is about 8.5% w/w.

In certain embodiments, the concentration of the PEDOT and the additional polymer in the at least one solvent is about 9% w/w. In further embodiments, the concentration of the PEDOT and the additional polymer in the at least one solvent is about 9.5% w/w. In yet further embodiments, the concentration of the PEDOT and the additional polymer in the at least one solvent is about 10% w/w.

In certain embodiments, the concentration of the cross-linker in the at least one solvent is about 0.01% to about 90% v/v. In further embodiments, the concentration of the cross-linker in the at least one solvent is about 0.01% v/v. In yet further embodiments, the concentration of the cross-linker in the at least one solvent is about 0.02% v/v. In still further embodiments, the concentration of the cross-linker in the at least one solvent is about 0.03% v/v. In certain embodiments, the concentration of the cross-linker in the at least one solvent is about 0.04% v/v. In further embodiments, the concentration of the cross-linker in the at least one solvent is about 0.05% v/v. In yet further embodiments, the concentration of the cross-linker in the at least one solvent is about 0.06% v/v. In still further embodiments, the concentration of the cross-linker in the at least one solvent is about 0.07% v/v. In certain embodiments, the concentration of the cross-linker in the at least one solvent is about 0.08% v/v. In further embodiments, the concentration of the cross-linker in the at least one solvent is about 0.09% v/v.

In certain embodiments, the concentration of the cross-linker in the at least one solvent is about 0.1% v/v. In further embodiments, the concentration of the cross-linker in the at least one solvent is about 0.2% v/v. In yet further embodiments, the concentration of the cross-linker in the at least one solvent is about 0.3% v/v. In still further embodiments, the concentration of the cross-linker in the at least one solvent is about 0.4% v/v. In certain embodiments, the concentration of the cross-linker in the at least one solvent is about 0.5% v/v. In further embodiments, the concentration of the cross-linker in the at least one solvent is about 0.6% v/v. In yet further embodiments, the concentration of the cross-linker in the at least one solvent is about 0.7% v/v. In still further embodiments, the concentration of the cross-linker in the at least one solvent is about 0.8% v/v. In certain embodiments, the concentration of the cross-linker in the at least one solvent is about 0.9% v/v.

In certain embodiments, the concentration of the cross-linker in the at least one solvent is about 1% v/v. In further embodiments, the concentration of the cross-linker in the at least one solvent is about 2% v/v. In yet further embodiments, the concentration of the cross-linker in the at least one solvent is about 3% v/v. In still further embodiments, the concentration of the cross-linker in the at least one solvent is about 4% v/v. In certain embodiments, the concentration of the cross-linker in the at least one solvent is about 5% v/v. In further embodiments, the concentration of the cross-linker in the at least one solvent is about 6% v/v. In yet further embodiments, the concentration of the cross-linker in the at least one solvent is about 7% v/v. In still further embodiments, the concentration of the cross-linker in the at least one solvent is about 8% v/v. In certain embodiments, the concentration of the cross-linker in the at least one solvent is about 9% v/v.

In certain embodiments, the concentration of the cross-linker in the at least one solvent is about 10% v/v. In further embodiments, the concentration of the cross-linker in the at least one solvent is about 20% v/v. In yet further embodiments, the concentration of the cross-linker in the at least one solvent is about 30% v/v. In still further embodiments, the concentration of the cross-linker in the at least one solvent is about 40% v/v. In certain embodiments, the concentration of the cross-linker in the at least one solvent is about 50% v/v. In further embodiments, the concentration of the cross-linker in the at least one solvent is about 60% v/v. In yet further embodiments, the concentration of the cross-linker in the at least one solvent is about 70% v/v. In still further embodiments, the concentration of the cross-linker in the at least one solvent is about 80% v/v. In certain embodiments, the concentration of the cross-linker in the at least one solvent is about 90% v/v.

In certain embodiments, prior to the induction of porosity and cross-linking, the method further comprises the step of: admixing the PEDOT and the additional polymer with a first solvent to form a dispersed polymer mixture.

In certain embodiments, the first solvent is water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the first solvent is water.

In certain embodiments, the admixing comprises heating or agitation. In further embodiments, the admixing does not comprise heating or agitation.

In certain embodiments, following the admixing and prior to the induction of porosity and cross-linking, the method further comprises the step of: combining the dispersed polymer mixture and the cross-linker or a cross-linker solution to form a combined mixture; wherein the cross-linker solution comprises the cross-linker and a second solvent.

In certain embodiments, the second solvent, when present, is selected from the group consisting of water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the second solvent, when present, is water.

In certain embodiments, following the combining and prior to the induction of porosity and cross-linking, the method further comprises the step of: applying the combined mixture to a surface or vessel. In further embodiments, the application comprises spraying, pouring, painting, or pipetting the combined mixture onto the surface, or dipping the surface in the combined mixture.

In certain embodiments, the induction of porosity and cross-linking comprises thermal annealing. In further embodiments, the induction of porosity and cross-linking does not comprise thermal annealing.

In certain embodiments, the combined mixture further comprises a non-solvent. In further embodiments, the induction of porosity and cross-linking comprises solvent-non-solvent interactions between the first and/or second solvent and the non-solvent.

In certain embodiments, the non-solvent is selected from the group consisting of toluene, γ-butyrolactone, chloroform, benzene, acetic acid, acetone, acetonitrile, 1-butanol, 2-butanol, 2-butanone t-butyl alcohol, carbon tetrachloride, chlorobenzene, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), triethyl amine, xylene, dimethyl sulfide, pyrrole, pyrrolidine, triethylamine, 18-crown-6, hexamethylbenzene, imidazole, propylene glycol, petroleum oils (which can include 15-60% alkanes, 30-60% naphthene, 3-30% aromatics, and up to 10% asphaltic by weight), organic oils (containing any compositions of lipids, fatty acids, and/or steroids, such as vegetable oil); vitamin E; or an ionic liquid such as: Bis(trifluoromethylsulfonyl)imides Butyltrimethylammonium, Diethylmethyl(2-methoxyethyl)ammonium, Ethyldimethylpropylammonium, 1,3-Dihydroxy-2-methylimidazolium, 1,3-Dihydroxyimidazolium, 1,3-Dimethoxy-2-methylimidazolium, 1,3-Dimethoxy-2-methylimidazolium hexafluorophosphate, 1,3-Dimethoxyimidazolium, Methyl-trioctylammonium, Solarpur, 1,2-Dimethyl-3-propylimidazolium, 1,3-Diethoxyimidazolium; 2-Hydroxyethyl-trimethylammonium L-(+)-lactate; Methyltrioctylammonium (hydrogen sulfate or thiosalicylate); Tetrabutylammonium (benzoate, bis-trifluoromethanesulfonimidate or heptadecafluorooctanesulfonate); 1-(2-Hydroxyethyl)-3-methylimidazolium dicyanamide; 1-(3-Cyanopropyl)-3-methylimidazolium (bis(trifluoromethylsulfonyl)amide, chloride, or dicyanamide); 1-Allyl-3-methylimidazolium (bis(trifluoromethylsulfonyl)imide, bromide, chloride, dicyanamide, iodide); 1-Benzyl-3-methylimidazolium (chloride, tetrafluoroborate, or bis(trifluoromethylsulfonyl)imide); 1-Butyl-1-methylpiperidinium hexafluorophosphate; 1-Butyl-2,3-dimethylimidazolium (chloride, hexafluorophosphate, or tetrafluoroborate); 1-Butyl-3-methylimidazolium (acetate, bis(trifluoromethylsulfonyl)imide, bromide, chloride, dicyanamide, hexafluoroantimonate, hexafluorophosphate, hydrogen sulfate, iodide, methanesulfonate, methyl sulfate, nitrate, octyl sulfate, tetrachloroaluminate, tetrafluoroborate, thiocyanate, or trifluoromethanesulfonate); 1-Decyl-3-methylimidazolium (chloride, or tetrafluoroborate); 1-Dodecyl-3-methylimidazolium iodide; 1-Ethyl-2,3-dimethylimidazolium tetrafluoroborate; 1-Ethyl-3-methylimidazolium (acetate, aminoacetate, (S)-2-aminopropionate, or 1,1,2,2-tetrafluoroethanesulfonate, bis(pentafluoroethylsulfonyl)imide, bis(trifluoromethylsulfonyl)imide, bromide, chloride, chloride-aluminum chloride, dicyanamide, diethyl phosphate, dimethyl phosphate, ethyl sulfate, hexafluorophosphate, hydrogen sulfate, iodide, L-(+)-lactate, methanesulfonate, methyl sulfate, tetrachloroaluminate, tetrafluoroborate, methylimidazolium thiocyanate, tosylate, or trifluoromethanesulfonate); 1-Hexyl-3-methylimidazolium (bis(trifluormethylsulfonyl)imide, chloride, hexafluorophosphate, 1-Hexyl-3-methylimidazolium iodide, or tetrafluoroborate); 1-Methyl-3-octylimidazolium (chloride, octylimidazolium hexafluorophosphate, or tetrafluoroborate); 1-Methyl-3-propylimidazolium (iodide or methyl carbonate solution); 1-Methylimidazolium (chloride or hydrogen sulfate); 1-Propyl-2,3-dimethyl-imidazolium iodide; 1,2-Dimethyl-3-propylimidazolium tris(trifluoromethylsulfonyl)methide; 1,3-Bis(cyanomethyl)imidazolium chloride purum; 1,3-Diethoxyimidazolium hexafluorophosphate; 1,3-Dimethoxyimidazolium (hexafluorophosphate or dimethyl phosphate); 3-(Triphenylphosphonio)propane-1-sulfonate; 4-(3-Butyl-1-imidazolio)-1-butanesulfonate; Cholin acetate; Cyclopropyldiphenylsulfonium tetrafluoroborate; Tetrabutylammonium (hydroxide, methanesulfonate, nitrite, nonafluorobutanesulfonate, or triiodide); Tetrabutylphosphonium (methanesulfonate or p-toluenesulfonate); Tetradodecylammonium (bromide or chloride); Tetraethylammonium trifluoromethanesulfonate; Tetraheptylammonium bromide; Tetrahexylammonium (hydrogensulfate, iodide, or tetrafluoroborate); Tetrakis(decyl)ammonium bromide; Tetramethylammonium hydroxide pentahydrate; Tetraoctylammonium chloride; Tributylmethylammonium (chloride, dibutyl phosphate, or methyl carbonate solution); Triethylsulfonium bis(trifluoromethylsulfonyl)imide; Trihexyltetradecylphosphonium (bis(2,4,4-trimethylpentyl)phosphinate, bis(trifluoromethylsulfonyl)amide, bromide, chloride, decanoate, or dicyanamide); or Tris(2-hydroxyethyl)methylammonium methyl sulfate.

In certain embodiments, the ratio of the first and/or second solvent to the non-solvent is about 1:100 to about 100:1. In further embodiments, the ratio of the first and/or second solvent to the non-solvent is selected from the group consisting of about 1:100, about 3:97, about 10:90, about 25:75, about 50:50, about 75:25, about 90:10, about 97:3, and about 100:1. In preferred embodiments, the ratio of the first and/or second solvent to the non-solvent is about 3:97. In further preferred embodiments, the ratio of the first and/or second solvent to the non-solvent is about 10:90.

In certain embodiments, the non-solvent further comprises a surfactant. In further embodiments, the surfactant is Triton X (Polyethylene glycol p-(1,1,3,3-tetramethylbutyl)-phenyl ether).

In certain embodiments, the induction of porosity and cross-linking further comprises mixing. In further embodiments, the mixing is selected from the group consisting of coarse mixing, high speed mixing, vortexing, and sonication.

In certain embodiments, the induction of porosity and cross-linking comprises cooling at a cooling rate the combined mixture to a sub-freezing temperature that is below the freezing point of the first and/or second solvent.

In certain embodiments, the cooling rate is about 0.1° C./min to about 10° C./min. In further embodiments, the cooling rate is about 0.1° C./min. In yet further embodiments, the cooling rate is about 0.2° C./min. In still further embodiments, the cooling rate is about 0.3° C./min. In certain embodiments, the cooling rate is about 0.4° C./min. In further embodiments, the cooling rate is about 0.5° C./min. In yet further embodiments, the cooling rate is about 0.6° C./min. In still further embodiments, the cooling rate is about 0.7° C./min. In certain embodiments, the cooling rate is about 0.8 ° C./min. In further embodiments, the cooling rate is about 0.9° C./min.

In certain embodiments, the cooling rate is about 1° C./min. In preferred embodiments, the cooling rate is about 2° C./min. In yet further embodiments, the cooling rate is about 3° C./min. In still further embodiments, the cooling rate is about 4° C./min. In certain embodiments, the cooling rate is about 5° C./min. In further embodiments, the cooling rate is about 6 ° C./min. In yet further embodiments, the cooling rate is about 7 ° C./min. In still further embodiments, the cooling rate is about 8° C./min. In certain embodiments, the cooling rate is about 9° C./min. In further embodiments, the cooling rate is about 10° C./min.

In certain embodiments, the sub-freezing temperature is about 0° C. to about −200 ° C. In further embodiments, the sub-freezing temperature is about 0° C. In yet further embodiments, the sub-freezing temperature is about −10° C. In preferred embodiments, the sub-freezing temperature is about −20° C. In still further embodiments, the sub-freezing temperature is about −30° C. In certain embodiments, the sub-freezing temperature is about −40° C. In further embodiments, the sub-freezing temperature is about −50° C. In yet further embodiments, the sub-freezing temperature is about −60° C. In still further embodiments, the sub-freezing temperature is about −70° C. In certain embodiments, the sub-freezing temperature is about −80° C. In further embodiments, the sub-freezing temperature is about −90° C.

In further embodiments, the sub-freezing temperature is about −100° C. In yet further embodiments, the sub-freezing temperature is about −110° C. In still further embodiments, the sub-freezing temperature is about −120° C. In certain embodiments, the sub-freezing temperature is about −13° C. In further embodiments, the sub-freezing temperature is about −140° C. In yet further embodiments, the sub-freezing temperature is about −150° C. In still further embodiments, the sub-freezing temperature is about −160° C. In certain embodiments, the sub-freezing temperature is about −170° C. In further embodiments, the sub-freezing temperature is about −180° C. In yet further embodiments, the sub-freezing temperature is about −190° C. In still further embodiments, the sub-freezing temperature is about −200° C.

In certain embodiments, the combined mixture further comprises nanoparticle fillers having an average nanoparticle diameter. In further embodiments, the nanoparticle fillers are selected from the group consisting of polymer nanoparticles, phenol nanoparticles, and camphene nanoparticles. In yet further embodiments, the nanoparticle fillers are polymer nanoparticles; and the polymer nanoparticles are PEG nanoparticles.

In certain embodiments, the average nanoparticle diameter is about 1 nm to about 100 In preferred embodiments, the average nanoparticle diameter is about 100 nm, about 10 or about 100 In further embodiments, the average nanoparticle diameter is about 1 nm. In yet further embodiments, the average nanoparticle diameter is about 10 nm. In still further embodiments, the average nanoparticle diameter is about 20 nm. In certain embodiments, the average nanoparticle diameter is about 30 nm. In further embodiments, the average nanoparticle diameter is about 40 nm. In yet further embodiments, the average nanoparticle diameter is about 50 nm. In still further embodiments, the average nanoparticle diameter is about 60 nm. In certain embodiments, the average nanoparticle diameter is about 70 nm. In further embodiments, the average nanoparticle diameter is about 80 nm. In yet further embodiments, the average nanoparticle diameter is about 90 nm.

In preferred embodiments, the average nanoparticle diameter is about 100 nm. In further embodiments, the average nanoparticle diameter is about 200 nm. In yet further embodiments, the average nanoparticle diameter is about 300 nm. In still further embodiments, the average nanoparticle diameter is about 400 nm. In certain embodiments, the average nanoparticle diameter is about 500 nm. In further embodiments, the average nanoparticle diameter is about 600 nm. In yet further embodiments, the average nanoparticle diameter is about 700 nm. In still further embodiments, the average nanoparticle diameter is about 800 nm. In certain embodiments, the average nanoparticle diameter is about 900 nm. In further embodiments, the average nanoparticle diameter is about 1 μm.

In certain embodiments, the average nanoparticle diameter is about 10 μm. In further embodiments, the average nanoparticle diameter is about 20 μm. In yet further embodiments, the average nanoparticle diameter is about 30 μm. In still further embodiments, the average nanoparticle diameter is about 40 μm. In certain embodiments, the average nanoparticle diameter is about 50 μm. In further embodiments, the average nanoparticle diameter is about 60 μm. In yet further embodiments, the average nanoparticle diameter is about 70 μm. In still further embodiments, the average nanoparticle diameter is about 80 μm. In certain embodiments, the average nanoparticle diameter is about 90 μm. In further embodiments, the average nanoparticle diameter is about 100 μm.

In certain embodiments, the induction of porosity and cross-linking further comprises removal of the nanoparticle fillers. In further embodiments, the removal of the nanoparticle fillers comprises melting, evaporating, subliming, or dissolving the filler nanoparticles. In yet further embodiments, dissolving the nanoparticle fillers comprises acid or base dissolution. In still further embodiments, dissolving the nanoparticle fillers comprises acid dissolution.

In certain embodiments, the combined mixture further comprises a third solvent; and the third solvent has a melting point which is higher than about 25° C.

In certain embodiments, the melting point of the third solvent is about 25° C. to about 120° C. In further embodiments, the melting point of the third solvent is about 25° C. In yet further embodiments, the melting point of the third solvent is about 30° C. In still further embodiments, the melting point of the third solvent is about 35° C. In certain embodiments, the melting point of the third solvent is about 40° C. In further embodiments, the melting point of the third solvent is about 45° C. In yet further embodiments, the melting point of the third solvent is about 50° C. In further embodiments, the melting point of the third solvent is about 55° C. In still further embodiments, the melting point of the third solvent is about 60° C.

In certain embodiments, the melting point of the third solvent is about 65° C. In further embodiments, the melting point of the third solvent is about 70° C. In yet further embodiments, the melting point of the third solvent is about 75° C. In still further embodiments, the melting point of the third solvent is about 80° C. In certain embodiments, the melting point of the third solvent is about 85° C. In further embodiments, the melting point of the third solvent is about 90° C. In yet further embodiments, the melting point of the third solvent is about 95° C. In still further embodiments, the melting point of the third solvent is about 100° C. In certain embodiments, the melting point of the third solvent is about 105° C. In further embodiments, the melting point of the third solvent is about 110° C. In yet further embodiments, the melting point of the third solvent is about 115° C. In still further embodiments, the melting point of the third solvent is about 120° C.

In further embodiments, the melting point of the third solvent is at least 25° C. In yet further embodiments, the melting point of the third solvent is at least 30° C. In still further embodiments, the melting point of the third solvent is at least 35° C. In certain embodiments, the melting point of the third solvent is at least 40° C. In further embodiments, the melting point of the third solvent is at least 45° C. In yet further embodiments, the melting point of the third solvent is at least 50° C. In further embodiments, the melting point of the third solvent is at least 55° C. In still further embodiments, the melting point of the third solvent is at least 60° C.

In certain embodiments, the melting point of the third solvent is at least 65° C. In further embodiments, the melting point of the third solvent is at least 70° C. In yet further embodiments, the melting point of the third solvent is at least 75° C. In still further embodiments, the melting point of the third solvent is at least 80° C. In certain embodiments, the melting point of the third solvent is at least 85° C. In further embodiments, the melting point of the third solvent is at least 90° C. In yet further embodiments, the melting point of the third solvent is at least 95° C. In still further embodiments, the melting point of the third solvent is at least 100° C. In certain embodiments, the melting point of the third solvent is at least 105° C. In further embodiments, the melting point of the third solvent is at least 110° C. In yet further embodiments, the melting point of the third solvent is at least 115° C. In still further embodiments, the melting point of the third solvent is at least 120° C.

In certain embodiments, the third solvent is selected from the group consisting of camphene, phenol, naphthalene, camphor, 18-crown-6, imidazole, and an alcohol, such as tertiary butanol, isopropyl alcohol, ethanol, or n-propanol.

In certain embodiments, the induction of porosity and cross-linking further comprises foaming the combined mixture to form a foamed mixture. In further embodiments, the method further comprises subliming or melting the foamed mixture at a temperature.

In certain embodiments, the temperature is about 20° C. to about 30° C. In further embodiments, the temperature is about 20° C. In yet further embodiments, the temperature is about 21° C. In still further embodiments, the temperature is about 22° C. In certain embodiments, the temperature is about 23° C. In further embodiments, the temperature is about 24° C. In yet further embodiments, the temperature is about 25° C. In still further embodiments, the temperature is about 26° C. In certain embodiments, the temperature is about 27° C. In further embodiments, the temperature is about 28° C. In yet further embodiments, the temperature is about 29° C. In still further embodiments, the temperature is about 30° C.

In certain embodiments, the foamed mixture further comprises nanoparticle fillers having an average nanoparticle diameter. In further embodiments, the nanoparticle fillers are selected from the group consisting of polymer nanoparticles, phenol nanoparticles, and camphene nanoparticles. In yet further embodiments, the nanoparticle fillers are polymer nanoparticles; and the polymer nanoparticles are PEG nanoparticles.

In certain embodiments, the average nanoparticle diameter is about 1 nm to about 100 μm. In preferred embodiments, the average nanoparticle diameter is about 100 nm, about 10 μm. or about 100 In further embodiments, the average nanoparticle diameter is about 1 nm. In yet further embodiments, the average nanoparticle diameter is about 10 nm. In still further embodiments, the average nanoparticle diameter is about 20 nm. In certain embodiments, the average nanoparticle diameter is about 30 nm. In further embodiments, the average nanoparticle diameter is about 40 nm. In yet further embodiments, the average nanoparticle diameter is about 50 nm. In still further embodiments, the average nanoparticle diameter is about 60 nm. In certain embodiments, the average nanoparticle diameter is about 70 nm. In further embodiments, the average nanoparticle diameter is about 80 nm. In yet further embodiments, the average nanoparticle diameter is about 90 nm.

In preferred embodiments, the average nanoparticle diameter is about 100 nm. In further embodiments, the average nanoparticle diameter is about 200 nm. In yet further embodiments, the average nanoparticle diameter is about 300 nm. In still further embodiments, the average nanoparticle diameter is about 400 nm. In certain embodiments, the average nanoparticle diameter is about 500 nm. In further embodiments, the average nanoparticle diameter is about 600 nm. In yet further embodiments, the average nanoparticle diameter is about 700 nm. In still further embodiments, the average nanoparticle diameter is about 800 nm. In certain embodiments, the average nanoparticle diameter is about 900 nm. In further embodiments, the average nanoparticle diameter is about 1 μm.

In certain embodiments, the average nanoparticle diameter is about 10 μm. In further embodiments, the average nanoparticle diameter is about 20 μm. In yet further embodiments, the average nanoparticle diameter is about 30 μm. In still further embodiments, the average nanoparticle diameter is about 40 μm. In certain embodiments, the average nanoparticle diameter is about 50 μm. In further embodiments, the average nanoparticle diameter is about 60 μm. In yet further embodiments, the average nanoparticle diameter is about 70 μm. In still further embodiments, the average nanoparticle diameter is about 80 μm. In certain embodiments, the average nanoparticle diameter is about 90 μm. In further embodiments, the average nanoparticle diameter is about 100 μm.

In certain embodiments, the method further comprises removal of the nanoparticle fillers. In further embodiments, the removal of the nanoparticle fillers comprises melting, evaporating, subliming, or dissolving the filler nanoparticles. In yet further embodiments, dissolving the nanoparticle fillers comprises acid or base dissolution. In still further embodiments, dissolving the nanoparticle fillers comprises acid dissolution.

In certain embodiments, the cross-linker comprises a combination of DVS and a metal oxide or metal hydrate. In further embodiments, the ratio of the DVS to the metal oxide or metal hydrate is about 1:99 to about 99:1. In yet further embodiments, the ratio of the DVS to the metal oxide or metal hydrate is about 1:99. In still further embodiments, the ratio of the DVS to the metal oxide or metal hydrate is about 1:90. In certain embodiments, the ratio of the DVS to the metal oxide or metal hydrate is about 1:80. In further embodiments, the ratio of the DVS to the metal oxide or metal hydrate is about 1:70. In yet further embodiments, the ratio of the DVS to the metal oxide or metal hydrate is about 1:60. In still further embodiments, the ratio of the DVS to the metal oxide or metal hydrate is about 1:50. In certain embodiments, the ratio of the DVS to the metal oxide or metal hydrate is about 1:40. In further embodiments, the ratio of the DVS to the metal oxide or metal hydrate is about 1:30. In yet further embodiments, the ratio of the DVS to the metal oxide or metal hydrate is about 1:20. In still further embodiments, the ratio of the DVS to the metal oxide or metal hydrate is about 1:10.

In certain embodiments, the ratio of the DVS to the metal oxide or metal hydrate is about 1:1. In further embodiments, the ratio of the DVS to the metal oxide or metal hydrate is about 10:1. In yet further embodiments, the ratio of the DVS to the metal oxide or metal hydrate is about 20:1. In still further embodiments, the ratio of the DVS to the metal oxide or metal hydrate is about 30:1. In certain embodiments, the ratio of the DVS to the metal oxide or metal hydrate is about 40:1. In further embodiments, the ratio of the DVS to the metal oxide or metal hydrate is about 50:1. In yet further embodiments, the ratio of the DVS to the metal oxide or metal hydrate is about 60:1. In still further embodiments, the ratio of the DVS to the metal oxide or metal hydrate is about 70:1. In certain embodiments, the ratio of the DVS to the metal oxide or metal hydrate is about 80:1. In further embodiments, the ratio of the DVS to the metal oxide or metal hydrate is about 90:1. In yet further embodiments, the ratio of the DVS to the metal oxide or metal hydrate is about 99:1.

In certain embodiments, the average pore diameter is about 1 nm to about 500 μm. In preferred embodiments, the average pore diameter is about 5 μm to about 500 μm. In yet further embodiments, the average pore diameter is about 5 μm. In still further embodiments, the average pore diameter is about 10 μm. In certain embodiments, the average pore diameter is about 50 μm. In further embodiments, the average pore diameter is about 100 μm. In yet further embodiments, the average pore diameter is about 200 μm. In still further embodiments, the average pore diameter is about 300 μm. In certain embodiments, the average pore diameter is about 400 μm. In further embodiments, the average pore diameter is about 500 μm.

In certain embodiments, the induction of porosity and cross-linking further comprises drying. In further embodiments, the drying is air drying or freeze-drying.

In certain embodiments, the induction of porosity and cross-linking further comprises dry annealing.

In further aspects, provided herein are methods of making a cross-linked porous polymeric material, the method comprising:

inducing porosity and cross-linking in a mixture comprising PEDOT, an additional polymer, a cross-linker, and at least one solvent;

wherein the induction of porosity and cross-linking comprises one or more steps selected from the group consisting of:

1) solvent-non-solvent interactions between the at least one solvent and a non-solvent;

2) cooling at a cooling rate to a sub-freezing temperature that is below the freezing point of the at least one solvent;

3) adding nanoparticle fillers having an average nanoparticle diameter and subsequent removal of the nanoparticle fillers; and

4) adding an additional solvent, wherein the additional solvent has a melting point which is higher than about 25° C. to form a high melting mixture, foaming the high melting mixture to form a foamed mixture, and optionally subliming or melting the foamed mixture;

thereby forming a cross-linked porous polymeric material;

wherein:

the cross-linked porous polymeric material comprises a plurality of pores having an average pore diameter;

the additional polymer is an acidic polymer, a basic polymer, a polyanionic polymer, a polycationic polymer, a sulfonate-containing polymer, a biopolymer, or an amphoteric polymer; and the cross-linker is a molecule with two or more vinyl functional groups, a metal oxide, a metal hydrate, or a combination thereof.

In certain embodiments, the additional polymer is selected from the group consisting of PSS, Poly(acrylamide), Poly(N-isopropyl acrylamide), Poly(N-octyl acrylamide), Poly(N-tert-butyl acrylamide), Poly(N-phenyl acrylamide), Poly(N-sec-butyl acrylamide), Poly(acrylic acid), Poly(benzyl acrylate), Poly(butyl acrylate), Poly(-chlorophenyl acrylate), Poly(-cyanoethyl acrylate), Poly(cyanomethyl acrylate), Poly(cyclohexyl acrylate), Poly(ethyl acrylate), Poly(2-ethylhexyl acrylate), Poly(hexyl acrylate), Poly(isobutyl acrylate), Poly(isopropyl acrylate), Poly(methyl acrylate), Poly(octyl acrylate), Poly(propyl acrylate), Poly(sec-butyl acrylate), Poly(stearyl acrylate), Poly(tert-butyl acrylate), Poly(2,2,3,3-Tetrafluoropropyl acrylate), Poly(acrylonitrile), Poly(methacrylonitrile), Poly(butylene adipate), Poly(ethylene adipate), Poly(propylene adipate), Poly(butylene), Poly(butyl ethylene), Poly(cyclohexylethylene), Poly(ethylene), Poly(heptylethylene), Poly(hexylethylene), Poly(isobutene), Poly(isobutylethylene), Poly(isopropylethylene), Poly(-methylbutene), Poly(octylethylene), Poly(pentylethylene), Poly(propylene), Poly(propylethylene), Poly(tert-butylethylene), Nylon 3-Poly(propiolactam), Nylon 6-Poly(caprolactam), Nylon 8-Polycapryllactam, Nylon 10-Poly(decano-10-lactam), Nylon 11-Poly(undecano-11-lactam), Nylon 12-Poly(dodecano-12-lactam), Nylon 4,6-Poly(tetramethylene adipamide), Nylon 6,6-Poly(hexamethylene adipamide), Nylon 6,9-Poly(hexamethylene azelamide), Nylon 6,10- Poly(hexamethylene sebacamide), Nylon 6,12-Poly(hexamethylene dodecanediamide), Nylon 10,1-Poly(decamethylene sebacamide), Poly(hexamethylene isophthalamide), Poly(hexamethylene teraphthalamide), Kevlar-Polyaramide, Nomex-Poly(m-phenylene terephthalamide), Poly(nonanmethylene teraphthalamide), Poly(p-pentamethylenedibenzoic anhydride), Poly(p-tetramethylenedibenzoic anhydride), Poly(sebacic anhydride), Poly(azelaic anhydride), Poly(1,2-butadiene), Poly(1,4-butadiene), Polycyclopentene, Poly(1-ethyl-1,4-butadiene), 1,4-Polyisoprene (cis and trans), Poly(1,4-pentadiene), Poly(1-pentenylene), Poly(dimethyl fumarate), Poly(dibutyl fumarate), Poly(diethyl fumarate), Poly(dipropyl fumarate), Poly(bisphenol A carbonate), Poly(4,4′-thiodiphenylene carbonate), Poly(bisphenol B carbonate), Poly(bisphenol F carbonate), Poly(ethylene carbonate), Poly(propylene carbonate), Poly(2,6,3′,5′-tetrachloro bisphenol A carbonate), Poly(tetramethyl bisphenol A carbonate), Cellulose Acetate, Methyl Cellulose, Ethyl Cellulose, Poly(chlorotrifluoroethylene), Poly(tetrafluoroethylene), Poly(vinyl bromide), Poly(vinyl chloride), Poly(vinyl fluoride), Poly(vinylidene chloride), Poly(vinylidene fluoride), Poly(methyl cyanoacrylate), Poly(ethyl cyanoacrylate), Poly(butyl cyanoacrylate), Poly(hexyl cyanoacrylate), Poly(octyl cyanoacrylate), Poly(1,2-butadiene), Poly(1,4-butadiene), Poly(1-pentenylene), Bisphenol-A diglycidyl ether epoxy resin, Bisphenol-F diglycidyl ether epoxy resin, Poly(bis-A diglycidyl ether-alt-ethylenediamine), Poly(bis-A diglycidyl ether-alt-hexamethylenediamine), Poly(bis-A diglycidyl ether-alt-octamethylenediamine), Poly(Bisphenol A isophthalate), Poly(Bisphenol A terephthalate), Poly(butylene isophthalate), Poly(butylene sebacate), Poly(butylene succinate), Poly(butylene terephthalate), Poly(ethylene sebacate), Poly(ethylene succinate), Poly(caprolactone), Poly(cyclohexylenedimethylene terephthalate), Poly(ethylene isophthalate), Poly(ethylene naphthalate), Poly(ethylene phthalate), Poly(ethylene terephthalate), Polyglycolide, Poly(hexylene sebacate), Poly(hexylene succinate), Poly(3-hydroxybutyrate), Poly(4-hydroxybutyrate), Polylactic acid, Poly(trimethylene succinate), Poly(trimethylene terephthalate), Polyacetal-Polyoxymethylene, Poly(3-butoxypropylene oxide), Poly(epichlorohydrin), Poly(ethylene glycol), Poly(hexamethylene oxide), Poly(3-methoxypropylene oxide), Poly[oxy(hexyloxymethyl)ethylene], Poly(oxymethylene-oxyethylene), Poly(oxymethylene-oxytetramethylene), Poly(propylene glycol), Poly(tetrahydrofuran), Poly(trimethylene glycol), Poly[1,1-bis(chloromethyl)trimethylene oxide], PEK-Poly(ether ketone), PEKK-Poly(ether ketone ketone), PEEK - Poly(ether ether ketone), Poly(ethyleneketone), Poly(propyleneketone), Poly(ether ether sulfone), Poly(ethersulfone), Poly(phenylsulfone), Bisphenol A Polysulfone, PoIy(1-chloro-1-butenylene) (Polychloroprene), Poly(1-bromo-1-butenylene) (Polybromoprene), Poly(4-bromostyrene), Poly(2-chlorostyrene), Poly(3-chlorostyrene), Poly(4-chlorostyrene), Poly(2,5-difluorostyrene), Poly(4-fluorostyrene), Poly(2-hydroxyethyl acrylate), Poly(2-hydroxyethyl methacrylate), Poly(2-hydroxypropyl methacrylate), Poly[(diethylene glycol)-alt-(1,6-hexamethylene diisocyanate)], Poly[(tetraethylene glycol)-alt-(1,6-hexamethylene diisocyanate)], Poly[(1,4-butanediol)-alt-(4,4′-diphenylmethane diisocyanate)], Poly[(ethylene glycol)-alt-(4,4′-diphenylmethane diisocyanate)], Poly[(polytetrahydrofuran 1000)-alt-(4,4′-diphenylmethane diisocyanate)], Poly(1,2-butadiene), Poly(l-pentenylene), Poly[dimethyl itaconate], Poly[di(n-propyl) itaconate], Poly[di(n-butyl) itaconate], Poly[di(n-hexyl) itaconate], Poly(p-phenylene), Poly(p-phenylene vinylene), Poly(p-xylene), Poly(2-chloro-p-xylylene), Poly(2,6-dimethyl-p-phenylene oxide), Poly(2,6-diphenyl-p-phenylene oxide), Poly(p-phenylene oxide), Poly(thio-1,4-phenylene), Poly(ethylene sulfide), Poly(propylene sulfide), Poly(vinyl alcohol), Poly(4-vinyl phenol), Poly(vinyl butyral), Poly(vinyl formal), Poly(vinyl acetate), Poly(vinyl benzoate), Poly(vinyl butyrate), Poly(vinyl caproate), Poly(vinyl formate), Poly(vinyl propionate), Poly(vinyl stearate), Poly(vinyl valerate), Poly(vinyl ethyl ketone), Poly(vinyl methyl ketone), Poly(methyl isopropenyl ketone), Poly(vinyl phenyl ketone), Poly(vinyl pyrrolidone), Poly(vinyl butyl sulfide), Poly(vinyl ethyl sulfide), Poly(vinyl methyl sulfide), Poly(vinyl phenyl sulfide), or Poly(vinyl propyl sulfide), Polysaccharides, such as cellulose, starch, glycogen, chitin, chitosan, pectin, callose, inulin, galactogen, amylose, amylopectin, chrysolaminarin, xylan, arabinoxylan, fucoidan, guar gum, and biopolymers such as alginate and collagen. In preferred embodiments, the additional polymer is PSS.

In certain embodiments, the cross-linker is a molecule with two or more vinyl functional groups. In further embodiments, the molecule with two or more vinyl functional groups is selected from the group consisting of DVS, 1,4-Bis(4-vinylphenoxy)butane, divinylbenzene, p-divinylbenzene, 4-Vinylbenzocyclobutene, Divinyl sulfone, 3,9-Divinyl-2,4,8,10-tetraoxaspiro[5.5]undecane, Divinyl sulfoxide, 1,4-Butanediol divinyl ether, 1,4-Cyclohexanedimethanol divinyl ether, 1,3-divinyl-1,1,3,3-tetramethyldisiloxane, Platinum(0)-1,3-divinyl-1,1,3,3-tetramethyldisiloxane, Di(ethylene glycol) divinyl ether, Poly(dimethylsiloxane-co-diphenylsiloxane) divinyl terminated, Poly(ethylene glycol) divinyl ether, Tri(ethylene glycol) divinyl Ether, 1,4-Pentadien-3-ol, Vinyl Acrylate, Protoporphyrin IX Dimethyl Ester, Protoporphyrin IX Zinc(II), 1,3-divinyl-5-isobutyl-5-methylhydantoin, 1,4-divinyl-1,1,2,2,3,3,4,4-octamethyltetrasilane, 3,6-divinyl-2-methyltetrahydropyran, Poly(Dimethylsiloxane), vinyl terminated, [1,3-Bis(2,6-diisopropylphenyl)-imidazolidinylidene][1,3-divinyl-1,1,3,3-tetramethyldisiloxane]platinum(0), [1,3-Bis(cyclohexyl)imidazol-2-ylidene][1,3-divinyl-1,1,3,3-tetramethyldisiloxane]platinum(0), 3,7,12,17-Tetramethyl-8,13-divinyl-2,18-porphinedipropionic acid, Kammerer's porphyrin, 3,7,12,17-Tetramethyl-8,13-divinyl-2,18-porphinedipropionic acid, [1,3-Bis(2,6-diisopropylphenyl)imidazol-2-ylidene][1,3-divinyl-1,1,3,3-tetramethyldisiloxane]platinum(0), Vinylboronic anhydride, 1,2,4-Trivinylcyclohexane, or butadiene. In preferred embodiments, the molecule with two or more vinyl functional groups is DVS.

In certain embodiments, the cross-linker is a metal oxide. In further embodiments, the metal oxide is selected from the group consisting of silver oxide, gold oxide, aluminum oxide, zinc oxide, copper oxide, magnesium oxide, calcium oxide, lithium oxide, iron oxide, chromium oxide, and titanium oxide.

In certain embodiments, the cross-linker is a metal hydrate. In further embodiments, the metal hydrate is selected from the group consisting of silver hydrate, gold hydrate, aluminum hydrate, zinc hydrate, copper hydrate, magnesium hydrate, calcium hydroxide, iron hydrate, and chromium (III) sulfate hydrate.

In certain embodiments, the at least one solvent is selected from the group consisting of water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the at least one solvent is water.

In certain embodiments, the concentration of the PEDOT and the additional polymer in the at least one solvent is about 0.5% w/w to about 10% w/w. In further embodiments, the concentration of the PEDOT and the additional polymer in the at least one solvent is about 0.5% w/w. In yet further embodiments, the concentration of the PEDOT and the additional polymer in the at least one solvent is about 0.6% w/w. In still further embodiments, the concentration of the PEDOT and the additional polymer in the at least one solvent is about 0.7% w/w. In certain embodiments, the concentration of the PEDOT and the additional polymer in the at least one solvent is about 0.8% w/w. In further embodiments, the concentration of the PEDOT and the additional polymer in the at least one solvent is about 0.9% w/w.

In certain embodiments, the concentration of the PEDOT and the additional polymer in the at least one solvent is about 1% w/w. In further embodiments, the concentration of the PEDOT and the additional polymer in the at least one solvent is about 1.5% w/w. In yet further embodiments, the concentration of the PEDOT and the additional polymer in the at least one solvent is about 2% w/w. In still further embodiments, the concentration of the PEDOT and the additional polymer in the at least one solvent is about 2.5% w/w.

In certain embodiments, the concentration of the PEDOT and the additional polymer in the at least one solvent is about 3% w/w. In further embodiments, the concentration of the PEDOT and the additional polymer in the at least one solvent is about 3.5% w/w. In yet further embodiments, the concentration of the PEDOT and the additional polymer in the at least one solvent is about 4% w/w. In still further embodiments, the concentration of the PEDOT and the additional polymer in the at least one solvent is about 4.5% w/w.

In certain embodiments, the concentration of the PEDOT and the additional polymer in the at least one solvent is about 5% w/w. In further embodiments, the concentration of the PEDOT and the additional polymer in the at least one solvent is about 5.5% w/w. In yet further embodiments, the concentration of the PEDOT and the additional polymer in the at least one solvent is about 6% w/w. In still further embodiments, the concentration of the PEDOT and the additional polymer in the at least one solvent is about 6.5% w/w.

In certain embodiments, the concentration of the PEDOT and the additional polymer in the at least one solvent is about 7% w/w. In further embodiments, the concentration of the PEDOT and the additional polymer in the at least one solvent is about 7.5% w/w. In yet further embodiments, the concentration of the PEDOT and the additional polymer in the at least one solvent is about 8% w/w. In still further embodiments, the concentration of the PEDOT and the additional polymer in the at least one solvent is about 8.5% w/w.

In certain embodiments, the concentration of the PEDOT and the additional polymer in the at least one solvent is about 9% w/w. In further embodiments, the concentration of the PEDOT and the additional polymer in the at least one solvent is about 9.5% w/w. In yet further embodiments, the concentration of the PEDOT and the additional polymer in the at least one solvent is about 10% w/w.

In certain embodiments, the concentration of the cross-linker in the at least one solvent is about 0.01% to about 90% v/v. In further embodiments, the concentration of the cross-linker in the at least one solvent is about 0.01% v/v. In yet further embodiments, the concentration of the cross-linker in the at least one solvent is about 0.02% v/v. In still further embodiments, the concentration of the cross-linker in the at least one solvent is about 0.03% v/v. In certain embodiments, the concentration of the cross-linker in the at least one solvent is about 0.04% v/v. In further embodiments, the concentration of the cross-linker in the at least one solvent is about 0.05% v/v. In yet further embodiments, the concentration of the cross-linker in the at least one solvent is about 0.06% v/v. In still further embodiments, the concentration of the cross-linker in the at least one solvent is about 0.07% v/v. In certain embodiments, the concentration of the cross-linker in the at least one solvent is about 0.08% v/v. In further embodiments, the concentration of the cross-linker in the at least one solvent is about 0.09% v/v.

In certain embodiments, the concentration of the cross-linker in the at least one solvent is about 0.1% v/v. In further embodiments, the concentration of the cross-linker in the at least one solvent is about 0.2% v/v. In yet further embodiments, the concentration of the cross-linker in the at least one solvent is about 0.3% v/v. In still further embodiments, the concentration of the cross-linker in the at least one solvent is about 0.4% v/v. In certain embodiments, the concentration of the cross-linker in the at least one solvent is about 0.5% v/v. In further embodiments, the concentration of the cross-linker in the at least one solvent is about 0.6% v/v. In yet further embodiments, the concentration of the cross-linker in the at least one solvent is about 0.7% v/v. In still further embodiments, the concentration of the cross-linker in the at least one solvent is about 0.8% v/v. In certain embodiments, the concentration of the cross-linker in the at least one solvent is about 0.9% v/v.

In certain embodiments, the concentration of the cross-linker in the at least one solvent is about 1% v/v. In further embodiments, the concentration of the cross-linker in the at least one solvent is about 2% v/v. In yet further embodiments, the concentration of the cross-linker in the at least one solvent is about 3% v/v. In still further embodiments, the concentration of the cross-linker in the at least one solvent is about 4% v/v. In certain embodiments, the concentration of the cross-linker in the at least one solvent is about 5% v/v. In further embodiments, the concentration of the cross-linker in the at least one solvent is about 6% v/v. In yet further embodiments, the concentration of the cross-linker in the at least one solvent is about 7% v/v. In still further embodiments, the concentration of the cross-linker in the at least one solvent is about 8% v/v. In certain embodiments, the concentration of the cross-linker in the at least one solvent is about 9% v/v.

In certain embodiments, the concentration of the cross-linker in the at least one solvent is about 10% v/v. In further embodiments, the concentration of the cross-linker in the at least one solvent is about 20% v/v. In yet further embodiments, the concentration of the cross-linker in the at least one solvent is about 30% v/v. In still further embodiments, the concentration of the cross-linker in the at least one solvent is about 40% v/v. In certain embodiments, the concentration of the cross-linker in the at least one solvent is about 50% v/v. In further embodiments, the concentration of the cross-linker in the at least one solvent is about 60% v/v. In yet further embodiments, the concentration of the cross-linker in the at least one solvent is about 70% v/v. In still further embodiments, the concentration of the cross-linker in the at least one solvent is about 80% v/v. In certain embodiments, the concentration of the cross-linker in the at least one solvent is about 90% v/v.

In certain embodiments, prior to the induction of porosity and cross-linking, the method further comprises the step of: admixing the PEDOT and the additional polymer with a first solvent to form a dispersed polymer mixture.

In certain embodiments, the first solvent is water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the first solvent is water.

In certain embodiments, the admixing comprises heating or agitation. In further embodiments, the admixing does not comprise heating or agitation.

In certain embodiments, following the admixing and prior to the induction of porosity and cross-linking, the method further comprises the step of: combining the dispersed polymer mixture and the cross-linker or a cross-linker solution to form a combined mixture; wherein the cross-linker solution comprises the cross-linker and a second solvent.

In certain embodiments, the second solvent, when present, is selected from the group consisting of water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the second solvent, when present, is water.

In certain embodiments, following the combining and prior to the induction of porosity and cross-linking, the method further comprises the step of: applying the combined mixture to a surface or vessel. In further embodiments, the application comprises spraying, pouring, painting, or pipetting the combined mixture onto the surface, or dipping the surface in the combined mixture.

In certain embodiments, the induction of porosity and cross-linking comprises thermal annealing. In further embodiments, the induction of porosity and cross-linking does not comprise thermal annealing.

In certain embodiments, the combined mixture further comprises a non-solvent. In further embodiments, the induction of porosity and cross-linking comprises solvent-non-solvent interactions between the first and/or second solvent and the non-solvent.

In certain embodiments, the non-solvent is selected from the group consisting of toluene, γ-butyrolactone, chloroform, benzene, acetic acid, acetone, acetonitrile, 1-butanol, 2-butanol, 2-butanone t-butyl alcohol, carbon tetrachloride, chlorobenzene, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), triethyl amine, xylene, dimethyl sulfide, pyrrole, pyrrolidine, triethylamine, 18-crown-6, hexamethylbenzene, imidazole, propylene glycol, petroleum oils (which can include 15-60% alkanes, 30-60% naphthene, 3-30% aromatics, and up to 10% asphaltic by weight), organic oils (containing any compositions of lipids, fatty acids, and/or steroids, such as vegetable oil); vitamin E; or an ionic liquid such as: Bis(trifluoromethylsulfonyl)imides Butyltrimethylammonium, Diethylmethyl(2-methoxyethyl)ammonium, Ethyldimethylpropylammonium, 1,3-Dihydroxy-2-methylimidazolium, 1,3-Dihydroxyimidazolium, 1,3-Dimethoxy-2-methylimidazolium, 1,3-Dimethoxy-2-methylimidazolium hexafluorophosphate, 1,3-Dimethoxyimidazolium, Methyl-trioctylammonium, Solarpur, 1,2-Dimethyl-3-propylimidazolium, 1,3-Diethoxyimidazolium; 2-Hydroxyethyl-trimethylammonium L-(+)-lactate; Methyltrioctylammonium (hydrogen sulfate or thiosalicylate); Tetrabutylammonium (benzoate, bis-trifluoromethanesulfonimidate or heptadecafluorooctanesulfonate); 1-(2-Hydroxyethyl)-3-methylimidazolium dicyanamide; 1-(3-Cyanopropyl)-3-methylimidazolium (bis(trifluoromethylsulfonyl)amide, chloride, or dicyanamide); 1-Allyl-3-methylimidazolium (bis(trifluoromethylsulfonyl)imide, bromide, chloride, dicyanamide, iodide); 1-Benzyl-3-methylimidazolium (chloride, tetrafluoroborate, or bis(trifluoromethylsulfonyl)imide); 1-Butyl-1-methylpiperidinium hexafluorophosphate; 1-Butyl-2,3-dimethylimidazolium (chloride, hexafluorophosphate, or tetrafluoroborate); 1-Butyl-3-methylimidazolium (acetate, bis(trifluoromethylsulfonyl)imide, bromide, chloride, dicyanamide, hexafluoroantimonate, hexafluorophosphate, hydrogen sulfate, iodide, methanesulfonate, methyl sulfate, nitrate, octyl sulfate, tetrachloroaluminate, tetrafluoroborate, thiocyanate, or trifluoromethanesulfonate); 1-Decyl-3-methylimidazolium (chloride, or tetrafluoroborate); 1-Dodecyl-3-methylimidazolium iodide; 1-Ethyl-2,3-dimethylimidazolium tetrafluoroborate; 1-Ethyl-3-methylimidazolium (acetate, aminoacetate, (S)-2-aminopropionate, or 1,1,2,2-tetrafluoroethanesulfonate, bis(pentafluoroethylsulfonyl)imide, bis(trifluoromethylsulfonyl)imide, bromide, chloride, chloride-aluminum chloride, dicyanamide, diethyl phosphate, dimethyl phosphate, ethyl sulfate, hexafluorophosphate, hydrogen sulfate, iodide, L-(+)-lactate, methanesulfonate, methyl sulfate, tetrachloroaluminate, tetrafluoroborate, methylimidazolium thiocyanate, tosylate, or trifluoromethanesulfonate); 1-Hexyl-3-methylimidazolium (bis(trifluormethylsulfonyl)imide, chloride, hexafluorophosphate, 1-Hexyl-3-methylimidazolium iodide, or tetrafluoroborate); 1-Methyl-3-octylimidazolium (chloride, octylimidazolium hexafluorophosphate, or tetrafluoroborate); 1-Methyl-3-propylimidazolium (iodide or methyl carbonate solution); 1-Methylimidazolium (chloride or hydrogen sulfate); 1-Propyl-2,3-dimethyl-imidazolium iodide; 1,2-Dimethyl-3-propylimidazolium tris(trifluoromethylsulfonyl)methide; 1,3-Bis(cyanomethyl)imidazolium chloride purum; 1,3-Diethoxyimidazolium hexafluorophosphate; 1,3-Dimethoxyimidazolium (hexafluorophosphate or dimethyl phosphate); 3-(Triphenylphosphonio)propane-1-sulfonate; 4-(3-Butyl-1-imidazolio)-1-butanesulfonate; Cholin acetate; Cyclopropyldiphenylsulfonium tetrafluoroborate; Tetrabutylammonium (hydroxide, methanesulfonate, nitrite, nonafluorobutanesulfonate, or triiodide); Tetrabutylphosphonium (methanesulfonate or p-toluenesulfonate); Tetradodecylammonium (bromide or chloride); Tetraethylammonium trifluoromethanesulfonate; Tetraheptylammonium bromide; Tetrahexylammonium (hydrogensulfate, iodide, or tetrafluoroborate); Tetrakis(decyl)ammonium bromide; Tetramethylammonium hydroxide pentahydrate; Tetraoctylammonium chloride; Tributylmethylammonium (chloride, dibutyl phosphate, or methyl carbonate solution); Triethylsulfonium bis(trifluoromethylsulfonyl)imide; Trihexyltetradecylphosphonium (bis(2,4,4-trimethylpentyl)phosphinate, bis(trifluoromethylsulfonyl)amide, bromide, chloride, decanoate, or dicyanamide); or Tris(2-hydroxyethyl)methylammonium methyl sulfate.

In certain embodiments, the ratio of the first and/or second solvent to the non-solvent is about 1:100 to about 100:1. In further embodiments, the ratio of the first and/or second solvent to the non-solvent is selected from the group consisting of about 1:100, about 3:97, about 10:90, about 25:75, about 50:50, about 75:25, about 90:10, about 97:3, and about 100:1. In preferred embodiments, the ratio of the first and/or second solvent to the non-solvent is about 3:97. In further preferred embodiments, the ratio of the first and/or second solvent to the non-solvent is about 10:90.

In certain embodiments, the non-solvent further comprises a surfactant. In further embodiments, the surfactant is Triton X (Polyethylene glycol p-(1,1,3,3-tetramethylbutyl)-phenyl ether).

In certain embodiments, the induction of porosity and cross-linking further comprises mixing. In further embodiments, the mixing is selected from the group consisting of coarse mixing, high speed mixing, vortexing, and sonication.

In certain embodiments, the induction of porosity and cross-linking comprises cooling at a cooling rate the combined mixture to a sub-freezing temperature that is below the freezing point of the first and/or second solvent.

In certain embodiments, the cooling rate is about 0.1° C./min to about 10° C./min. In further embodiments, the cooling rate is about 0.1° C./min. In yet further embodiments, the cooling rate is about 0.2° C./min. In still further embodiments, the cooling rate is about 0.3° C./min. In certain embodiments, the cooling rate is about 0.4° C./min. In further embodiments, the cooling rate is about 0.5° C./min. In yet further embodiments, the cooling rate is about 0.6° C./min. In still further embodiments, the cooling rate is about 0.7° C./min. In certain embodiments, the cooling rate is about 0.8° C./min. In further embodiments, the cooling rate is about 0.9° C./min.

In certain embodiments, the cooling rate is about 1° C./min. In preferred embodiments, the cooling rate is about 2° C./min. In yet further embodiments, the cooling rate is about 3° C./min. In still further embodiments, the cooling rate is about 4° C./min. In certain embodiments, the cooling rate is about 5° C./min. In further embodiments, the cooling rate is about 6° C../min. In yet further embodiments, the cooling rate is about 7° C./min. In still further embodiments, the cooling rate is about 8° C./min. In certain embodiments, the cooling rate is about 9° C./min. In further embodiments, the cooling rate is about 10° C./min.

In certain embodiments, the sub-freezing temperature is about 0° C. to about −20° C. In further embodiments, the sub-freezing temperature is about 0° C. In yet further embodiments, the sub-freezing temperature is about −10° C. In preferred embodiments, the sub-freezing temperature is about −20° C. In still further embodiments, the sub-freezing temperature is about −30° C. In certain embodiments, the sub-freezing temperature is about −4° C. In further embodiments, the sub-freezing temperature is about −50° C. In yet further embodiments, the sub-freezing temperature is about −60° C. In still further embodiments, the sub-freezing temperature is about −70° C. In certain embodiments, the sub-freezing temperature is about −80° C. In further embodiments, the sub-freezing temperature is about −90° C.

In further embodiments, the sub-freezing temperature is about −100° C. In yet further embodiments, the sub-freezing temperature is about −110° C. In still further embodiments, the sub-freezing temperature is about −120° C. In certain embodiments, the sub-freezing temperature is about −130° C. In further embodiments, the sub-freezing temperature is about −140° C. In yet further embodiments, the sub-freezing temperature is about −150° C. In still further embodiments, the sub-freezing temperature is about −160° C. In certain embodiments, the sub-freezing temperature is about −170° C. In further embodiments, the sub-freezing temperature is about −180° C. In yet further embodiments, the sub-freezing temperature is about −190° C. In still further embodiments, the sub-freezing temperature is about −200° C.

In certain embodiments, the combined mixture further comprises nanoparticle fillers having an average nanoparticle diameter. In further embodiments, the nanoparticle fillers are selected from the group consisting of polymer nanoparticles, phenol nanoparticles, and camphene nanoparticles. In yet further embodiments, the nanoparticle fillers are polymer nanoparticles; and the polymer nanoparticles are PEG nanoparticles.

In certain embodiments, the average nanoparticle diameter is about 1 nm to about 100 μm. In preferred embodiments, the average nanoparticle diameter is about 100 nm, about 10 μm, or about 100 μm. In further embodiments, the average nanoparticle diameter is about 1 nm. In yet further embodiments, the average nanoparticle diameter is about 10 nm. In still further embodiments, the average nanoparticle diameter is about 20 nm. In certain embodiments, the average nanoparticle diameter is about 30 nm. In further embodiments, the average nanoparticle diameter is about 40 nm. In yet further embodiments, the average nanoparticle diameter is about 50 nm. In still further embodiments, the average nanoparticle diameter is about 60 nm. In certain embodiments, the average nanoparticle diameter is about 70 nm. In further embodiments, the average nanoparticle diameter is about 80 nm. In yet further embodiments, the average nanoparticle diameter is about 90 nm.

In preferred embodiments, the average nanoparticle diameter is about 100 nm. In further embodiments, the average nanoparticle diameter is about 200 nm. In yet further embodiments, the average nanoparticle diameter is about 300 nm. In still further embodiments, the average nanoparticle diameter is about 400 nm. In certain embodiments, the average nanoparticle diameter is about 500 nm. In further embodiments, the average nanoparticle diameter is about 600 nm. In yet further embodiments, the average nanoparticle diameter is about 700 nm. In still further embodiments, the average nanoparticle diameter is about 800 nm. In certain embodiments, the average nanoparticle diameter is about 900 nm. In further embodiments, the average nanoparticle diameter is about 1 μm.

In certain embodiments, the average nanoparticle diameter is about 10 μm. In further embodiments, the average nanoparticle diameter is about 20 μm. In yet further embodiments, the average nanoparticle diameter is about 30 μm. In still further embodiments, the average nanoparticle diameter is about 40 μm. In certain embodiments, the average nanoparticle diameter is about 50 μm. In further embodiments, the average nanoparticle diameter is about 60 μm. In yet further embodiments, the average nanoparticle diameter is about 70 μm. In still further embodiments, the average nanoparticle diameter is about 80 μm. In certain embodiments, the average nanoparticle diameter is about 90 μm. In further embodiments, the average nanoparticle diameter is about 100 μm.

In certain embodiments, the induction of porosity and cross-linking further comprises removal of the nanoparticle fillers. In further embodiments, the removal of the nanoparticle fillers comprises melting, evaporating, subliming, or dissolving the filler nanoparticles. In yet further embodiments, dissolving the nanoparticle fillers comprises acid or base dissolution. In still further embodiments, dissolving the nanoparticle fillers comprises acid dissolution.

In certain embodiments, the combined mixture further comprises a third solvent; and the third solvent has a melting point which is higher than about 25° C.

In certain embodiments, the melting point of the third solvent is about 25° C. to about 120° C. In further embodiments, the melting point of the third solvent is about 25° C. In yet further embodiments, the melting point of the third solvent is about 30° C. In still further embodiments, the melting point of the third solvent is about 35° C. In certain embodiments, the melting point of the third solvent is about 40° C. In further embodiments, the melting point of the third solvent is about 45° C. In yet further embodiments, the melting point of the third solvent is about 50° C. In further embodiments, the melting point of the third solvent is about 55° C. In still further embodiments, the melting point of the third solvent is about 6° C.

In certain embodiments, the melting point of the third solvent is about 65 ° C. In further embodiments, the melting point of the third solvent is about 70° C. In yet further embodiments, the melting point of the third solvent is about 75° C. In still further embodiments, the melting point of the third solvent is about 8° C. In certain embodiments, the melting point of the third solvent is about 85 ° C. In further embodiments, the melting point of the third solvent is about 90° C. In yet further embodiments, the melting point of the third solvent is about 95° C. In still further embodiments, the melting point of the third solvent is about 100° C. In certain embodiments, the melting point of the third solvent is about 105° C. In further embodiments, the melting point of the third solvent is about 110° C. In yet further embodiments, the melting point of the third solvent is about 115° C. In still further embodiments, the melting point of the third solvent is about 120° C.

In further embodiments, the melting point of the third solvent is at least 25° C. In yet further embodiments, the melting point of the third solvent is at least 30° C. In still further embodiments, the melting point of the third solvent is at least 35° C. In certain embodiments, the melting point of the third solvent is at least 40° C. In further embodiments, the melting point of the third solvent is at least 45° C. In yet further embodiments, the melting point of the third solvent is at least 50° C. In further embodiments, the melting point of the third solvent is at least 55° C. In still further embodiments, the melting point of the third solvent is at least 60° C.

In certain embodiments, the melting point of the third solvent is at least 65° C. In further embodiments, the melting point of the third solvent is at least 70° C. In yet further embodiments, the melting point of the third solvent is at least 75° C. In still further embodiments, the melting point of the third solvent is at least 80° C. In certain embodiments, the melting point of the third solvent is at least 85° C. In further embodiments, the melting point of the third solvent is at least 90° C. In yet further embodiments, the melting point of the third solvent is at least 95° C. In still further embodiments, the melting point of the third solvent is at least 100° C. In certain embodiments, the melting point of the third solvent is at least 105° C. In further embodiments, the melting point of the third solvent is at least 110° C. In yet further embodiments, the melting point of the third solvent is at least 115° C. In still further embodiments, the melting point of the third solvent is at least 120° C.

In certain embodiments, the third solvent is selected from the group consisting of camphene, phenol, naphthalene, camphor, 18-crown-6, imidazole, and an alcohol, such as tertiary butanol, isopropyl alcohol, ethanol, or n-propanol.

In certain embodiments, the induction of porosity and cross-linking further comprises foaming the combined mixture to form a foamed mixture. In further embodiments, the method further comprises subliming or melting the foamed mixture at a temperature.

In certain embodiments, the temperature is about 20° C. to about 30° C. In further embodiments, the temperature is about 20° C. In yet further embodiments, the temperature is about 21° C. In still further embodiments, the temperature is about 22° C. In certain embodiments, the temperature is about 23° C. In further embodiments, the temperature is about 24° C. In yet further embodiments, the temperature is about 25° C. In still further embodiments, the temperature is about 26° C. In certain embodiments, the temperature is about 27° C. In further embodiments, the temperature is about 28° C. In yet further embodiments, the temperature is about 29° C. In still further embodiments, the temperature is about 30° C.

In certain embodiments, the foamed mixture further comprises nanoparticle fillers having an average nanoparticle diameter. In further embodiments, the nanoparticle fillers are selected from the group consisting of polymer nanoparticles, phenol nanoparticles, and camphene nanoparticles. In yet further embodiments, the nanoparticle fillers are polymer nanoparticles; and the polymer nanoparticles are PEG nanoparticles.

In certain embodiments, the average nanoparticle diameter is about 1 nm to about 100 μm. In preferred embodiments, the average nanoparticle diameter is about 100 nm, about 10 μm, or about 100 μm. In further embodiments, the average nanoparticle diameter is about 1 nm. In yet further embodiments, the average nanoparticle diameter is about 10 nm. In still further embodiments, the average nanoparticle diameter is about 20 nm. In certain embodiments, the average nanoparticle diameter is about 30 nm. In further embodiments, the average nanoparticle diameter is about 40 nm. In yet further embodiments, the average nanoparticle diameter is about 50 nm. In still further embodiments, the average nanoparticle diameter is about 60 nm. In certain embodiments, the average nanoparticle diameter is about 70 nm. In further embodiments, the average nanoparticle diameter is about 80 nm. In yet further embodiments, the average nanoparticle diameter is about 90 nm.

In preferred embodiments, the average nanoparticle diameter is about 100 nm. In further embodiments, the average nanoparticle diameter is about 200 nm. In yet further embodiments, the average nanoparticle diameter is about 300 nm. In still further embodiments, the average nanoparticle diameter is about 400 nm. In certain embodiments, the average nanoparticle diameter is about 500 nm. In further embodiments, the average nanoparticle diameter is about 600 nm. In yet further embodiments, the average nanoparticle diameter is about 700 nm. In still further embodiments, the average nanoparticle diameter is about 800 nm. In certain embodiments, the average nanoparticle diameter is about 900 nm. In further embodiments, the average nanoparticle diameter is about 1 μm.

In certain embodiments, the average nanoparticle diameter is about 10 μm. In further embodiments, the average nanoparticle diameter is about 20 μm. In yet further embodiments, the average nanoparticle diameter is about 30 μm. In still further embodiments, the average nanoparticle diameter is about 40 μm. In certain embodiments, the average nanoparticle diameter is about 50 μm. In further embodiments, the average nanoparticle diameter is about 60 μm. In yet further embodiments, the average nanoparticle diameter is about 70 μm. In still further embodiments, the average nanoparticle diameter is about 80 μm. In certain embodiments, the average nanoparticle diameter is about 90 μm. In further embodiments, the average nanoparticle diameter is about 100 μm.

In certain embodiments, the method further comprises removal of the nanoparticle fillers. In further embodiments, the removal of the nanoparticle fillers comprises melting, evaporating, subliming, or dissolving the filler nanoparticles. In yet further embodiments, dissolving the nanoparticle fillers comprises acid or base dissolution. In still further embodiments, dissolving the nanoparticle fillers comprises acid dissolution.

In certain embodiments, the cross-linker comprises a combination of DVS and a metal oxide or metal hydrate. In further embodiments, the ratio of the DVS to the metal oxide or metal hydrate is about 1:99 to about 99:1. In yet further embodiments, the ratio of the DVS to the metal oxide or metal hydrate is about 1:99. In still further embodiments, the ratio of the DVS to the metal oxide or metal hydrate is about 1:90. In certain embodiments, the ratio of the DVS to the metal oxide or metal hydrate is about 1:80. In further embodiments, the ratio of the DVS to the metal oxide or metal hydrate is about 1:70. In yet further embodiments, the ratio of the DVS to the metal oxide or metal hydrate is about 1:60. In still further embodiments, the ratio of the DVS to the metal oxide or metal hydrate is about 1:50. In certain embodiments, the ratio of the DVS to the metal oxide or metal hydrate is about 1:40. In further embodiments, the ratio of the DVS to the metal oxide or metal hydrate is about 1:30. In yet further embodiments, the ratio of the DVS to the metal oxide or metal hydrate is about 1:20. In still further embodiments, the ratio of the DVS to the metal oxide or metal hydrate is about 1:10.

In certain embodiments, the ratio of the DVS to the metal oxide or metal hydrate is about 1:1. In further embodiments, the ratio of the DVS to the metal oxide or metal hydrate is about 10:1. In yet further embodiments, the ratio of the DVS to the metal oxide or metal hydrate is about 20:1. In still further embodiments, the ratio of the DVS to the metal oxide or metal hydrate is about 30:1. In certain embodiments, the ratio of the DVS to the metal oxide or metal hydrate is about 40:1. In further embodiments, the ratio of the DVS to the metal oxide or metal hydrate is about 50:1. In yet further embodiments, the ratio of the DVS to the metal oxide or metal hydrate is about 60:1. In still further embodiments, the ratio of the DVS to the metal oxide or metal hydrate is about 70:1. In certain embodiments, the ratio of the DVS to the metal oxide or metal hydrate is about 80:1. In further embodiments, the ratio of the DVS to the metal oxide or metal hydrate is about 90:1. In yet further embodiments, the ratio of the DVS to the metal oxide or metal hydrate is about 99:1.

In certain embodiments, the average pore diameter is about 1 nm to about 500 μm. In preferred embodiments, the average pore diameter is about 5 μm to about 500 μm. In yet further embodiments, the average pore diameter is about 5 μm. In still further embodiments, the average pore diameter is about 10 μm. In certain embodiments, the average pore diameter is about 50 μm. In further embodiments, the average pore diameter is about 100 μm. In yet further embodiments, the average pore diameter is about 200 μm. In still further embodiments, the average pore diameter is about 300 μm. In certain embodiments, the average pore diameter is about 400 μm. In further embodiments, the average pore diameter is about 500 μm.

In certain embodiments, the induction of porosity and cross-linking further comprises drying. In further embodiments, the drying is air drying or freeze-drying.

In certain embodiments, the induction of porosity and cross-linking further comprises dry annealing.

In yet further aspects, provided herein are methods of making a porous polymeric material, the method comprising:

admixing PEDOT and an additional polymer with a first solvent to form a dispersed polymer mixture;

combining the dispersed polymer mixture and a cross-linker or a cross-linker solution to form a combined mixture; wherein the cross-linker solution comprises the cross-linker and a second solvent;

applying the combined mixture to a surface or vessel;

inducing cross-linking and porosity in the combined mixture to form a porous polymeric material comprising a cross-linked polymer, wherein the porous polymeric material comprises a plurality of pores having an average pore diameter;

wherein:

the additional polymer is selected from the group consisting of an acidic polymer, a basic polymer, a polyanionic polymer, a sulfonate-containing polymer, a biopolymer, and an amphoteric polymer; and

the cross-linker is selected from the group consisting of a molecule with two or more vinyl functional groups, a metal oxide, and a metal hydrate, or a combination thereof.

In certain embodiments, the additional polymer is selected from the group consisting of PSS, Poly(acrylamide), Poly(N-isopropyl acrylamide), Poly(N-octyl acrylamide), Poly(N-tert-butyl acrylamide), Poly(N-phenyl acrylamide), Poly(N-sec-butyl acrylamide), Poly(acrylic acid), Poly(benzyl acrylate), Poly(butyl acrylate), Poly(-chlorophenyl acrylate), Poly(-cyanoethyl acrylate), Poly(cyanomethyl acrylate), Poly(cyclohexyl acrylate), Poly(ethyl acrylate), Poly(2-ethylhexyl acrylate), Poly(hexyl acrylate), Poly(isobutyl acrylate), Poly(isopropyl acrylate), Poly(methyl acrylate), Poly(octyl acrylate), Poly(propyl acrylate), Poly(sec-butyl acrylate), Poly(stearyl acrylate), Poly(tert-butyl acrylate), Poly(2,2,3,3-Tetrafluoropropyl acrylate), Poly(acrylonitrile), Poly(methacrylonitrile), Poly(butylene adipate), Poly(ethylene adipate), Poly(propylene adipate), Poly(butylene), Poly(butyl ethylene), Poly(cyclohexylethylene), Poly(ethylene), Poly(heptylethylene), Poly(hexylethylene), Poly(isobutene), Poly(isobutylethylene), Poly(isopropylethylene), Poly(-methylbutene), Poly(octylethylene), Poly(pentylethylene), Poly(propylene), Poly(propylethylene), Poly(tert-butylethylene), Nylon 3-Poly(propiolactam), Nylon 6-Poly(caprolactam), Nylon 8-Polycapryllactam, Nylon 10-Poly(decano-10-lactam), Nylon 11-Poly(undecano-11-lactam), Nylon 12-Poly(dodecano-12-lactam), Nylon 4,6-Poly(tetramethylene adipamide), Nylon 6,6-Poly(hexamethylene adipamide), Nylon 6,9-Poly(hexamethylene azelamide), Nylon 6,10-Poly(hexamethylene sebacamide), Nylon 6,12-Poly(hexamethylene dodecanediamide), Nylon 10,10-Poly(decamethylene sebacamide), Poly(hexamethylene isophthalamide), Poly(hexamethylene teraphthalamide), Kevlar-Polyaramide, Nomex-Poly(m-phenylene terephthalamide), Poly(nonanmethylene teraphthalamide), Poly(p-pentamethylenedibenzoic anhydride), Poly(p-tetramethylenedibenzoic anhydride), Poly(sebacic anhydride), Poly(azelaic anhydride), Poly(1,2-butadiene), Poly(1,4-butadiene), Polycyclopentene, Poly(l-ethyl-1,4-butadiene), 1,4-Polyisoprene (cis and trans), Poly(1,4-pentadiene), Poly(1-pentenylene), Poly(dimethyl fumarate), Poly(dibutyl fumarate), Poly(diethyl fumarate), Poly(dipropyl fumarate), Poly(bisphenol A carbonate), Poly(4,4′-thiodiphenylene carbonate), Poly(bisphenol B carbonate), Poly(bisphenol F carbonate), Poly(ethylene carbonate), Poly(propylene carbonate), Poly(2,6,3′,5′-tetrachloro bisphenol A carbonate), Poly(tetramethyl bisphenol A carbonate), Cellulose Acetate, Methyl Cellulose, Ethyl Cellulose, Poly(chlorotrifluoroethylene), Poly(tetrafluoroethylene), Poly(vinyl bromide), Poly(vinyl chloride), Poly(vinyl fluoride), Poly(vinylidene chloride), Poly(vinylidene fluoride), Poly(methyl cyanoacrylate), Poly(ethyl cyanoacrylate), Poly(butyl cyanoacrylate), Poly(hexyl cyanoacrylate), Poly(octyl cyanoacrylate), Poly(1,2-butadiene), Poly(1,4-butadiene), Poly(1-pentenylene), Bisphenol-A diglycidyl ether epoxy resin, Bisphenol-F diglycidyl ether epoxy resin, Poly(bis-A diglycidyl ether-alt-ethylenediamine), Poly(bis-A diglycidyl ether-alt-hexamethylenediamine), Poly(bis-A diglycidyl ether-alt octamethylenediamine), Poly(Bisphenol A isophthalate), Poly(Bisphenol A terephthalate), Poly(butylene isophthalate), Poly(butylene sebacate), Poly(butylene succinate), Poly(butylene terephthalate), Poly(ethylene sebacate), Poly(ethylene succinate), Poly(caprolactone), Poly(cyclohexylenedimethylene terephthalate), Poly(ethylene isophthalate), Poly(ethylene naphthalate), Poly(ethylene phthalate), Poly(ethylene terephthalate), Polyglycolide, Poly(hexylene sebacate), Poly(hexylene succinate), Poly(3-hydroxybutyrate), Poly(4-hydroxybutyrate), Polylactic acid, Poly(trimethylene succinate), Poly(trimethylene terephthalate), Polyacetal-Polyoxymethylene, Poly(3-butoxypropylene oxide), Poly(epichlorohydrin), Poly(ethylene glycol), Poly(hexamethylene oxide), Poly(3-methoxypropylene oxide), Poly[oxy(hexyloxymethyl)ethylene], Poly(oxymethylene-oxyethylene), Poly(oxymethylene-oxytetramethylene), Poly(propylene glycol), Poly(tetrahydrofuran), Poly(trimethylene glycol), Poly[1,1-bis(chloromethyl)trimethylene oxide], PEK-Poly(ether ketone), PEKK-Poly(ether ketone ketone), PEEK-Poly(ether ether ketone), Poly(ethyleneketone), Poly(propyleneketone), Poly(ether ether sulfone), Poly(ethersulfone), Poly(phenylsulfone), Bisphenol A Polysulfone, PoIy(1-chloro-1-butenylene) (Polychloroprene), Poly(1-bromo-1-butenylene) (Polybromoprene), Poly(4-bromostyrene), Poly(2-chlorostyrene), Poly(3-chlorostyrene), Poly(4-chlorostyrene), Poly(2,5-difluorostyrene), Poly(4-fluorostyrene), Poly(2-hydroxyethyl acrylate), Poly(2-hydroxyethyl methacrylate), Poly(2-hydroxypropyl methacrylate), Poly[(diethylene glycol)-alt-(1,6-hexamethylene diisocyanate)], Poly[(tetraethylene glycol)-alt-(1,6-hexamethylene diisocyanate)], Poly[(1,4-butanediol)-alt-(4,4′-diphenylmethane diisocyanate)], Poly[(ethylene glycol)-alt-(4,4′-diphenylmethane diisocyanate)], Poly[(polytetrahydrofuran 1000)-alt-(4,4′-diphenylmethane diisocyanate)], Poly(1,2-butadiene), Poly(1-pentenylene), Poly[dimethyl itaconate], Poly[di(n-propyl) itaconate], Poly[di(n-butyl) itaconate], Poly[di(n-hexyl) itaconate], Poly(p-phenylene), Poly(p-phenylene vinylene), Poly(p-xylene), Poly(2-chloro-p-xylylene), Poly(2,6-dimethyl-p-phenylene oxide), Poly(2,6-diphenyl-p-phenylene oxide), Poly(p-phenylene oxide), Poly(thio-1,4-phenylene), Poly(ethylene sulfide), Poly(propylene sulfide), Poly(vinyl alcohol), Poly(4-vinyl phenol), Poly(vinyl butyral), Poly(vinyl formal), Poly(vinyl acetate), Poly(vinyl benzoate), Poly(vinyl butyrate), Poly(vinyl caproate), Poly(vinyl formate), Poly(vinyl propionate), Poly(vinyl stearate), Poly(vinyl valerate), Poly(vinyl ethyl ketone), Poly(vinyl methyl ketone), Poly(methyl isopropenyl ketone), Poly(vinyl phenyl ketone), Poly(vinyl pyrrolidone), Poly(vinyl butyl sulfide), Poly(vinyl ethyl sulfide), Poly(vinyl methyl sulfide), Poly(vinyl phenyl sulfide), or Poly(vinyl propyl sulfide), Polysaccharides, such as cellulose, starch, glycogen, chitin, chitosan, pectin, callose, inulin, galactogen, amylose, amylopectin, chrysolaminarin, xylan, arabinoxylan, fucoidan, guar gum, and biopolymers such as alginate and collagen. In preferred embodiments, the additional polymer is PSS.

In certain embodiments, the cross-linker is a molecule with two or more vinyl functional groups. In further embodiments, the molecule with two or more vinyl functional groups is selected from the group consisting of DVS, 1,4-Bis(4-vinylphenoxy)butane, divinylbenzene, p-divinylbenzene, 4-Vinylbenzocyclobutene, Divinyl sulfone, 3,9-Divinyl-2,4,8,10-tetraoxaspiro[5.5]undecane, Divinyl sulfoxide, 1,4-Butanediol divinyl ether, 1,4-Cyclohexanedimethanol divinyl ether, 1,3-divinyl-1,1,3,3-tetramethyldisiloxane, Platinum(0)-1,3-divinyl-1,1,3,3-tetramethyldisiloxane, Di(ethylene glycol) divinyl ether, Poly(dimethylsiloxane-co-diphenylsiloxane) divinyl terminated, Poly(ethylene glycol) divinyl ether, Tri(ethylene glycol) divinyl Ether, 1,4-Pentadien-3-ol, Vinyl Acrylate, Protoporphyrin IX Dimethyl Ester, Protoporphyrin IX Zinc(II), 1,3-divinyl-5-isobutyl-5-methylhydantoin, 1,4-divinyl-1,1,2,2,3,3,4,4-octamethyltetrasilane, 3,6-divinyl-2-methyltetrahydropyran, Poly(Dimethylsiloxane), vinyl terminated, [1,3-Bis(2,6-diisopropylphenyl)-imidazolidinylidene][1,3-divinyl-1,1,3,3-tetramethyldisiloxane]platinum(0), [1,3-Bis(cyclohexyl)imidazol-2-ylidene][1,3-divinyl-1,1,3,3-tetramethyldisiloxane]platinum(0), 3,7,12,17-Tetramethyl-8,13-divinyl-2,18-porphinedipropionic acid, Kammerer's porphyrin, 3,7,12,17-Tetramethyl-8,13-divinyl-2,18-porphinedipropionic acid, [1,3-Bis(2,6-diisopropylphenyl)imidazol-2-ylidene][1,3-divinyl-1,1,3,3-tetramethyldisiloxane]platinum(0), Vinylboronic anhydride, 1,2,4-Trivinylcyclohexane, or butadiene. In preferred embodiments, the molecule with two or more vinyl functional groups is DVS.

In certain embodiments, the cross-linker is a metal oxide. In further embodiments, the metal oxide is selected from the group consisting of silver oxide, gold oxide, aluminum oxide, zinc oxide, copper oxide, magnesium oxide, calcium oxide, lithium oxide, iron oxide, chromium oxide, and titanium oxide.

In certain embodiments, the cross-linker is a metal hydrate. In further embodiments, the metal hydrate is selected from the group consisting of silver hydrate, gold hydrate, aluminum hydrate, zinc hydrate, copper hydrate, magnesium hydrate, calcium hydroxide, iron hydrate, and chromium (III) sulfate hydrate.

In certain embodiments, the at least one solvent is selected from the group consisting of water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the at least one solvent is water.

In certain embodiments, the concentration of the PEDOT and the additional polymer in the at least one solvent is about 0.5% w/w to about 10% w/w. In further embodiments, the concentration of the PEDOT and the additional polymer in the at least one solvent is about 0.5% w/w. In yet further embodiments, the concentration of the PEDOT and the additional polymer in the at least one solvent is about 0.6% w/w. In still further embodiments, the concentration of the PEDOT and the additional polymer in the at least one solvent is about 0.7% w/w. In certain embodiments, the concentration of the PEDOT and the additional polymer in the at least one solvent is about 0.8% w/w. In further embodiments, the concentration of the PEDOT and the additional polymer in the at least one solvent is about 0.9% w/w.

In certain embodiments, the concentration of the PEDOT and the additional polymer in the at least one solvent is about 1% w/w. In further embodiments, the concentration of the PEDOT and the additional polymer in the at least one solvent is about 1.5% w/w. In yet further embodiments, the concentration of the PEDOT and the additional polymer in the at least one solvent is about 2% w/w. In still further embodiments, the concentration of the PEDOT and the additional polymer in the at least one solvent is about 2.5% w/w.

In certain embodiments, the concentration of the PEDOT and the additional polymer in the at least one solvent is about 3% w/w. In further embodiments, the concentration of the PEDOT and the additional polymer in the at least one solvent is about 3.5% w/w. In yet further embodiments, the concentration of the PEDOT and the additional polymer in the at least one solvent is about 4% w/w. In still further embodiments, the concentration of the PEDOT and the additional polymer in the at least one solvent is about 4.5% w/w.

In certain embodiments, the concentration of the PEDOT and the additional polymer in the at least one solvent is about 5% w/w. In further embodiments, the concentration of the PEDOT and the additional polymer in the at least one solvent is about 5.5% w/w. In yet further embodiments, the concentration of the PEDOT and the additional polymer in the at least one solvent is about 6% w/w. In still further embodiments, the concentration of the PEDOT and the additional polymer in the at least one solvent is about 6.5% w/w.

In certain embodiments, the concentration of the PEDOT and the additional polymer in the at least one solvent is about 7% w/w. In further embodiments, the concentration of the PEDOT and the additional polymer in the at least one solvent is about 7.5% w/w. In yet further embodiments, the concentration of the PEDOT and the additional polymer in the at least one solvent is about 8% w/w. In still further embodiments, the concentration of the PEDOT and the additional polymer in the at least one solvent is about 8.5% w/w.

In certain embodiments, the concentration of the PEDOT and the additional polymer in the at least one solvent is about 9% w/w. In further embodiments, the concentration of the PEDOT and the additional polymer in the at least one solvent is about 9.5% w/w. In yet further embodiments, the concentration of the PEDOT and the additional polymer in the at least one solvent is about 10% w/w.

In certain embodiments, the concentration of the cross-linker in the at least one solvent is about 0.01% to about 90% v/v. In further embodiments, the concentration of the cross-linker in the at least one solvent is about 0.01% v/v. In yet further embodiments, the concentration of the cross-linker in the at least one solvent is about 0.02% v/v. In still further embodiments, the concentration of the cross-linker in the at least one solvent is about 0.03% v/v. In certain embodiments, the concentration of the cross-linker in the at least one solvent is about 0.04% v/v.

In further embodiments, the concentration of the cross-linker in the at least one solvent is about 0.05% v/v. In yet further embodiments, the concentration of the cross-linker in the at least one solvent is about 0.06% v/v. In still further embodiments, the concentration of the cross-linker in the at least one solvent is about 0.07% v/v. In certain embodiments, the concentration of the cross-linker in the at least one solvent is about 0.08% v/v. In further embodiments, the concentration of the cross-linker in the at least one solvent is about 0.09% v/v.

In certain embodiments, the concentration of the cross-linker in the at least one solvent is about 0.1% v/v. In further embodiments, the concentration of the cross-linker in the at least one solvent is about 0.2% v/v. In yet further embodiments, the concentration of the cross-linker in the at least one solvent is about 0.3% v/v. In still further embodiments, the concentration of the cross-linker in the at least one solvent is about 0.4% v/v. In certain embodiments, the concentration of the cross-linker in the at least one solvent is about 0.5% v/v. In further embodiments, the concentration of the cross-linker in the at least one solvent is about 0.6% v/v. In yet further embodiments, the concentration of the cross-linker in the at least one solvent is about 0.7% v/v. In still further embodiments, the concentration of the cross-linker in the at least one solvent is about 0.8% v/v. In certain embodiments, the concentration of the cross-linker in the at least one solvent is about 0.9% v/v.

In certain embodiments, the concentration of the cross-linker in the at least one solvent is about 1% v/v. In further embodiments, the concentration of the cross-linker in the at least one solvent is about 2% v/v. In yet further embodiments, the concentration of the cross-linker in the at least one solvent is about 3% v/v. In still further embodiments, the concentration of the cross-linker in the at least one solvent is about 4% v/v. In certain embodiments, the concentration of the cross-linker in the at least one solvent is about 5% v/v. In further embodiments, the concentration of the cross-linker in the at least one solvent is about 6% v/v. In yet further embodiments, the concentration of the cross-linker in the at least one solvent is about 7% v/v. In still further embodiments, the concentration of the cross-linker in the at least one solvent is about 8% v/v. In certain embodiments, the concentration of the cross-linker in the at least one solvent is about 9% v/v.

In certain embodiments, the concentration of the cross-linker in the at least one solvent is about 10% v/v. In further embodiments, the concentration of the cross-linker in the at least one solvent is about 20% v/v. In yet further embodiments, the concentration of the cross-linker in the at least one solvent is about 30% v/v. In still further embodiments, the concentration of the cross-linker in the at least one solvent is about 40% v/v. In certain embodiments, the concentration of the cross-linker in the at least one solvent is about 50% v/v. In further embodiments, the concentration of the cross-linker in the at least one solvent is about 60% v/v. In yet further embodiments, the concentration of the cross-linker in the at least one solvent is about 70% v/v. In still further embodiments, the concentration of the cross-linker in the at least one solvent is about 80% v/v. In certain embodiments, the concentration of the cross-linker in the at least one solvent is about 90% v/v.

In certain embodiments, the first solvent is water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the first solvent is water.

In certain embodiments, the admixing comprises heating or agitation. In further embodiments, the admixing does not comprise heating or agitation.

In certain embodiments, the second solvent, when present, is selected from the group consisting of water, acetic acid, acetone, acetonitrile, benzene, 1-butanol, 2-butanol, 2-butanone t-butyl alcohol, carbon tetrachloride, chlorobenzene, chloroform, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), toluene, triethyl amine, xylene, dimethyl sulfide, pyrrole, pyrrolidine, and triethylamine. In preferred embodiments, the second solvent, when present, is water.

In certain embodiments, the application comprises spraying, pouring, painting, or pipetting the combined mixture onto the surface, or dipping the surface in the combined mixture.

In certain embodiments, the induction of porosity and cross-linking comprises thermal annealing. In further embodiments, the induction of porosity and cross-linking does not comprise thermal annealing.

In certain embodiments, the combined mixture further comprises a non-solvent. In further embodiments, the induction of porosity and cross-linking comprises solvent-non-solvent interactions between the first and/or second solvent and the non-solvent.

In certain embodiments, the non-solvent is selected from the group consisting of toluene, γ-butyrolactone, chloroform, benzene, acetic acid, acetone, acetonitrile, 1-butanol, 2-butanol, 2-butanone t-butyl alcohol, carbon tetrachloride, chlorobenzene, cyclohexane, 1,2-dichloroethane, diethylene glycol, diethyl ether, diglyme (diethylene glycol dimethyl ether)1,2-dimethoxy-ethane (glyme, DME), dimethyl-formamide (DMF), dimethyl sulfoxide (DMSO), 1,4-dioxane, ethanol, ethyl acetate, ethylene glycol, glycerin, heptane, hexamethylphosphoramide (HMPA), hexamethylphosphoroustriamide (HMPT), hexane, methanol, methyl t-butylether (MTBE), methylene chloride, N-methyl-2-pyrrolidinone (NMP), nitromethane, pentane, petroleum ether (ligroine), 1-propanol, 2-propanol, pyridine, tetrahydrofuran (THF), triethyl amine, xylene, dimethyl sulfide, pyrrole, pyrrolidine, triethylamine, 18-crown-6, hexamethylbenzene, imidazole, propylene glycol, petroleum oils (which can include 15 60% alkanes, 30-60% naphthene, 3-30% aromatics, and up to 10% asphaltic by weight), organic oils (containing any compositions of lipids, fatty acids, and/or steroids, such as vegetable oil); vitamin E; or an ionic liquid such as: Bis(trifluoromethylsulfonyl)imides Butyltrimethylammonium, Diethylmethyl(2-methoxyethyl)ammonium, Ethyldimethylpropylammonium, 1,3-Dihydroxy-2-methylimidazolium, 1,3-Dihydroxyimidazolium, 1,3-Dimethoxy-2-methylimidazolium, 1,3-Dimethoxy-2-methylimidazolium hexafluorophosphate, 1,3-Dimethoxyimidazolium, Methyl-trioctylammonium, Solarpur, 1,2-Dimethyl-3-propylimidazolium, 1,3-Diethoxyimidazolium; 2-Hydroxyethyl-trimethylammonium L-(+)-lactate; Methyltrioctylammonium (hydrogen sulfate or thiosalicylate); Tetrabutylammonium (benzoate, bis-trifluoromethanesulfonimidate or heptadecafluorooctanesulfonate); 1-(2-Hydroxyethyl)-3-methylimidazolium dicyanamide; 1-(3-Cyanopropyl)-3-methylimidazolium (bis(trifluoromethylsulfonyl)amide, chloride, or dicyanamide); 1-Allyl-3-methylimidazolium (bis(trifluoromethylsulfonyl)imide, bromide, chloride, dicyanamide, iodide); 1-Benzyl-3-methylimidazolium (chloride, tetrafluoroborate, or bis(trifluoromethylsulfonyl)imide); 1-Butyl-1-methylpiperidinium hexafluorophosphate; 1-Butyl-2,3-dimethylimidazolium (chloride, hexafluorophosphate, or tetrafluoroborate); 1-Butyl-3-methylimidazolium (acetate, bis(trifluoromethylsulfonyl)imide, bromide, chloride, dicyanamide, hexafluoroantimonate, hexafluorophosphate, hydrogen sulfate, iodide, methanesulfonate, methyl sulfate, nitrate, octyl sulfate, tetrachloroaluminate, tetrafluoroborate, thiocyanate, or trifluoromethanesulfonate); 1-Decyl-3-methylimidazolium (chloride, or tetrafluoroborate); 1-Dodecyl-3-methylimidazolium iodide; 1-Ethyl-2,3-dimethylimidazolium tetrafluoroborate; 1-Ethyl-3-methylimidazolium (acetate, aminoacetate, (S)-2-aminopropionate, or 1,1,2,2-tetrafluoroethanesulfonate, bis(pentafluoroethylsulfonyl)imide, bis(trifluoromethylsulfonyl)imide, bromide, chloride, chloride-aluminum chloride, dicyanamide, diethyl phosphate, dimethyl phosphate, ethyl sulfate, hexafluorophosphate, hydrogen sulfate, iodide, L-(+)-lactate, methanesulfonate, methyl sulfate, tetrachloroaluminate, tetrafluoroborate, methylimidazolium thiocyanate, tosylate, or trifluoromethanesulfonate); 1-Hexyl-3-methylimidazolium (bis(trifluormethylsulfonyl)imide, chloride, hexafluorophosphate, 1-Hexyl-3-methylimidazolium iodide, or tetrafluoroborate); 1-Methyl-3-octylimidazolium (chloride, octylimidazolium hexafluorophosphate, or tetrafluoroborate); 1-Methyl-3-propylimidazolium (iodide or methyl carbonate solution); 1-Methylimidazolium (chloride or hydrogen sulfate); 1-Propyl-2,3-dimethyl-imidazolium iodide; 1,2-Dimethyl-3-propylimidazolium tris(trifluoromethylsulfonyl)methide; 1,3-Bis(cyanomethyl)imidazolium chloride purum; 1,3-Diethoxyimidazolium hexafluorophosphate; 1,3-Dimethoxyimidazolium (hexafluorophosphate or dimethyl phosphate); 3-(Triphenylphosphonio)propane-l-sulfonate; 4-(3-Butyl-1-imidazolio)-1-butanesulfonate; Cholin acetate; Cyclopropyldiphenylsulfonium tetrafluoroborate; Tetrabutylammonium (hydroxide, methanesulfonate, nitrite, nonafluorobutanesulfonate, or triiodide); Tetrabutylphosphonium (methanesulfonate or p-toluenesulfonate); Tetradodecylammonium (bromide or chloride); Tetraethylammonium trifluoromethanesulfonate; Tetraheptylammonium bromide; Tetrahexylammonium (hydrogensulfate, iodide, or tetrafluoroborate); Tetrakis(decyl)ammonium bromide; Tetramethylammonium hydroxide pentahydrate; Tetraoctylammonium chloride; Tributylmethylammonium (chloride, dibutyl phosphate, or methyl carbonate solution); Triethylsulfonium bis(trifluoromethylsulfonyl)imide; Trihexyltetradecylphosphonium (bis(2,4,4-trimethylpentyl)phosphinate, bis(trifluoromethylsulfonyl)amide, bromide, chloride, decanoate, or dicyanamide); or Tris(2-hydroxyethyl)methylammonium methyl sulfate.

In certain embodiments, the ratio of the first and/or second solvent to the non-solvent is about 1:100 to about 100:1. In further embodiments, the ratio of the first and/or second solvent to the non-solvent is selected from the group consisting of about 1:100, about 3:97, about 10:90, about 25:75, about 50:50, about 75:25, about 90:10, about 97:3, and about 100:1. In preferred embodiments, the ratio of the first and/or second solvent to the non-solvent is about 3:97. In further preferred embodiments, the ratio of the first and/or second solvent to the non-solvent is about 10:90.

In certain embodiments, the non-solvent further comprises a surfactant. In further embodiments, the surfactant is Triton X (Polyethylene glycol p-(1,1,3,3-tetramethylbutyl)-phenyl ether).

In certain embodiments, the induction of porosity and cross-linking further comprises mixing. In further embodiments, the mixing is selected from the group consisting of coarse mixing, high speed mixing, vortexing, and sonication.

In certain embodiments, the induction of porosity and cross-linking comprises cooling at a cooling rate the combined mixture to a sub-freezing temperature that is below the freezing point of the first and/or second solvent.

In certain embodiments, the cooling rate is about 0.1° C./min to about 10° C./min. In further embodiments, the cooling rate is about 0.1° C./min. In yet further embodiments, the cooling rate is about 0.2° C./min. In still further embodiments, the cooling rate is about 0.3° C./min. In certain embodiments, the cooling rate is about 0.4° C./min. In further embodiments, the cooling rate is about 0.5° C./min. In yet further embodiments, the cooling rate is about 0.6° C./min. In still further embodiments, the cooling rate is about 0.7° C./min. In certain embodiments, the cooling rate is about 0.8° C./min. In further embodiments, the cooling rate is about 0.9° C./min.

In certain embodiments, the cooling rate is about 1° C./min. In preferred embodiments, the cooling rate is about 2° C./min. In yet further embodiments, the cooling rate is about 3° C./min. In still further embodiments, the cooling rate is about 4° C./min. In certain embodiments, the cooling rate is about 5° C./min. In further embodiments, the cooling rate is about 6° C./min. In yet further embodiments, the cooling rate is about 7° C./min. In still further embodiments, the cooling rate is about 8° C./min. In certain embodiments, the cooling rate is about 9° C./min. In further embodiments, the cooling rate is about 10° C./min.

In certain embodiments, the sub-freezing temperature is about 0° C. to about −200° C. In further embodiments, the sub-freezing temperature is about 0° C. In yet further embodiments, the sub-freezing temperature is about −10° C. In preferred embodiments, the sub-freezing temperature is about −20° C. In still further embodiments, the sub-freezing temperature is about −30° C. In certain embodiments, the sub-freezing temperature is about −40° C. In further embodiments, the sub-freezing temperature is about −50° C. In yet further embodiments, the sub-freezing temperature is about −60° C. In still further embodiments, the sub-freezing temperature is about −70° C. In certain embodiments, the sub-freezing temperature is about −80° C. In further embodiments, the sub-freezing temperature is about −90° C.

In further embodiments, the sub-freezing temperature is about −100° C. In yet further embodiments, the sub-freezing temperature is about −110° C. In still further embodiments, the sub-freezing temperature is about −120° C. In certain embodiments, the sub-freezing temperature is about −130° C. In further embodiments, the sub-freezing temperature is about −140° C. In yet further embodiments, the sub-freezing temperature is about −150° C. In still further embodiments, the sub-freezing temperature is about −160° C. In certain embodiments, the sub-freezing temperature is about −170° C. In further embodiments, the sub-freezing temperature is about −180° C. In yet further embodiments, the sub-freezing temperature is about −190° C. In still further embodiments, the sub-freezing temperature is about −200° C.

In certain embodiments, the combined mixture further comprises nanoparticle fillers having an average nanoparticle diameter. In further embodiments, the nanoparticle fillers are selected from the group consisting of polymer nanoparticles, phenol nanoparticles, and camphene nanoparticles. In yet further embodiments, the nanoparticle fillers are polymer nanoparticles; and the polymer nanoparticles are PEG nanoparticles.

In certain embodiments, the average nanoparticle diameter is about 1 nm to about 100 μm. In preferred embodiments, the average nanoparticle diameter is about 100 nm, about 10 μm. or about 100 μm. In further embodiments, the average nanoparticle diameter is about 1 nm. In yet further embodiments, the average nanoparticle diameter is about 10 nm. In still further embodiments, the average nanoparticle diameter is about 20 nm. In certain embodiments, the average nanoparticle diameter is about 30 nm. In further embodiments, the average nanoparticle diameter is about 40 nm. In yet further embodiments, the average nanoparticle diameter is about 50 nm. In still further embodiments, the average nanoparticle diameter is about 60 nm. In certain embodiments, the average nanoparticle diameter is about 70 nm. In further embodiments, the average nanoparticle diameter is about 80 nm. In yet further embodiments, the average nanoparticle diameter is about 90 nm.

In preferred embodiments, the average nanoparticle diameter is about 100 nm. In further embodiments, the average nanoparticle diameter is about 200 nm. In yet further embodiments, the average nanoparticle diameter is about 300 nm. In still further embodiments, the average nanoparticle diameter is about 400 nm. In certain embodiments, the average nanoparticle diameter is about 500 nm. In further embodiments, the average nanoparticle diameter is about 600 nm. In yet further embodiments, the average nanoparticle diameter is about 700 nm. In still further embodiments, the average nanoparticle diameter is about 800 nm. In certain embodiments, the average nanoparticle diameter is about 900 nm. In further embodiments, the average nanoparticle diameter is about 1 μm.

In certain embodiments, the average nanoparticle diameter is about 10 μm. In further embodiments, the average nanoparticle diameter is about 20 μm. In yet further embodiments, the average nanoparticle diameter is about 30 μm. In still further embodiments, the average nanoparticle diameter is about 40 μm. In certain embodiments, the average nanoparticle diameter is about 50 μm. In further embodiments, the average nanoparticle diameter is about 60 μm. In yet further embodiments, the average nanoparticle diameter is about 70 μm. In still further embodiments, the average nanoparticle diameter is about 80 μm. In certain embodiments, the average nanoparticle diameter is about 90 μm. In further embodiments, the average nanoparticle diameter is about 100 μm.

In certain embodiments, the induction of porosity and cross-linking further comprises removal of the nanoparticle fillers. In further embodiments, the removal of the nanoparticle fillers comprises melting, evaporating, subliming, or dissolving the filler nanoparticles. In yet further embodiments, dissolving the nanoparticle fillers comprises acid or base dissolution. In still further embodiments, dissolving the nanoparticle fillers comprises acid dissolution.

In certain embodiments, the combined mixture further comprises a third solvent; and the third solvent has a melting point which is higher than about 25° C.

In certain embodiments, the melting point of the third solvent is about 25° C. to about 120° C. In further embodiments, the melting point of the third solvent is about 25° C. In yet further embodiments, the melting point of the third solvent is about 30° C. In still further embodiments, the melting point of the third solvent is about 35° C. In certain embodiments, the melting point of the third solvent is about 40° C. In further embodiments, the melting point of the third solvent is about 45° C. In yet further embodiments, the melting point of the third solvent is about 50° C. In further embodiments, the melting point of the third solvent is about 55° C. In still further embodiments, the melting point of the third solvent is about 60° C.

In certain embodiments, the melting point of the third solvent is about 65° C. In further embodiments, the melting point of the third solvent is about 70° C. In yet further embodiments, the melting point of the third solvent is about 75° C. In still further embodiments, the melting point of the third solvent is about 80° C. In certain embodiments, the melting point of the third solvent is about 85° C. In further embodiments, the melting point of the third solvent is about 90° C. In yet further embodiments, the melting point of the third solvent is about 95° C. In still further embodiments, the melting point of the third solvent is about 100° C. In certain embodiments, the melting point of the third solvent is about 105° C. In further embodiments, the melting point of the third solvent is about 110° C. In yet further embodiments, the melting point of the third solvent is about 115° C. In still further embodiments, the melting point of the third solvent is about 120° C.

In further embodiments, the melting point of the third solvent is at least 25° C. In yet further embodiments, the melting point of the third solvent is at least 30° C. In still further embodiments, the melting point of the third solvent is at least 35° C. In certain embodiments, the melting point of the third solvent is at least 40° C. In further embodiments, the melting point of the third solvent is at least 45° C. In yet further embodiments, the melting point of the third solvent is at least 50° C. In further embodiments, the melting point of the third solvent is at least 55° C. In still further embodiments, the melting point of the third solvent is at least 60° C.

In certain embodiments, the melting point of the third solvent is at least 65° C. In further embodiments, the melting point of the third solvent is at least 70° C. In yet further embodiments, the melting point of the third solvent is at least 75° C. In still further embodiments, the melting point of the third solvent is at least 80° C. In certain embodiments, the melting point of the third solvent is at least 85° C. In further embodiments, the melting point of the third solvent is at least 90° C. In yet further embodiments, the melting point of the third solvent is at least 95° C. In still further embodiments, the melting point of the third solvent is at least 100° C. In certain embodiments, the melting point of the third solvent is at least 105° C. In further embodiments, the melting point of the third solvent is at least 110° C. In yet further embodiments, the melting point of the third solvent is at least 115° C. In still further embodiments, the melting point of the third solvent is at least 120° C.

In certain embodiments, the third solvent is selected from the group consisting of camphene, phenol, naphthalene, camphor, 18-crown-6, imidazole, and an alcohol, such as tertiary butanol, isopropyl alcohol, ethanol, or n-propanol.

In certain embodiments, the induction of porosity and cross-linking further comprises foaming the combined mixture to form a foamed mixture. In further embodiments, the method further comprises subliming or melting the foamed mixture at a temperature.

In certain embodiments, the temperature is about 20° C. to about 30° C. In further embodiments, the temperature is about 20° C. In yet further embodiments, the temperature is about 21° C. In still further embodiments, the temperature is about 22° C. In certain embodiments, the temperature is about 23° C. In further embodiments, the temperature is about 24° C. In yet further embodiments, the temperature is about 25° C. In still further embodiments, the temperature is about 26° C. In certain embodiments, the temperature is about 27° C. In further embodiments, the temperature is about 28° C. In yet further embodiments, the temperature is about 29° C. In still further embodiments, the temperature is about 30° C.

In certain embodiments, the foamed mixture further comprises nanoparticle fillers having an average nanoparticle diameter. In further embodiments, the nanoparticle fillers are selected from the group consisting of polymer nanoparticles, phenol nanoparticles, and camphene nanoparticles. In yet further embodiments, the nanoparticle fillers are polymer nanoparticles; and the polymer nanoparticles are PEG nanoparticles.

In certain embodiments, the average nanoparticle diameter is about 1 nm to about 100 In preferred embodiments, the average nanoparticle diameter is about 100 nm, about 10 μm. or about 100 μm. In further embodiments, the average nanoparticle diameter is about 1 nm. In yet further embodiments, the average nanoparticle diameter is about 10 nm. In still further embodiments, the average nanoparticle diameter is about 20 nm. In certain embodiments, the average nanoparticle diameter is about 30 nm. In further embodiments, the average nanoparticle diameter is about 40 nm. In yet further embodiments, the average nanoparticle diameter is about 50 nm. In still further embodiments, the average nanoparticle diameter is about 60 nm. In certain embodiments, the average nanoparticle diameter is about 70 nm. In further embodiments, the average nanoparticle diameter is about 80 nm. In yet further embodiments, the average nanoparticle diameter is about 90 nm.

In preferred embodiments, the average nanoparticle diameter is about 100 nm. In further embodiments, the average nanoparticle diameter is about 200 nm. In yet further embodiments, the average nanoparticle diameter is about 300 nm. In still further embodiments, the average nanoparticle diameter is about 400 nm. In certain embodiments, the average nanoparticle diameter is about 500 nm. In further embodiments, the average nanoparticle diameter is about 600 nm. In yet further embodiments, the average nanoparticle diameter is about 700 nm. In still further embodiments, the average nanoparticle diameter is about 800 nm. In certain embodiments, the average nanoparticle diameter is about 900 nm. In further embodiments, the average nanoparticle diameter is about 1 μm.

In certain embodiments, the average nanoparticle diameter is about 10 μm. In further embodiments, the average nanoparticle diameter is about 20 μm. In yet further embodiments, the average nanoparticle diameter is about 30 μm. In still further embodiments, the average nanoparticle diameter is about 40 μm. In certain embodiments, the average nanoparticle diameter is about 50 μm. In further embodiments, the average nanoparticle diameter is about 60 μm. In yet further embodiments, the average nanoparticle diameter is about 70 μm. In still further embodiments, the average nanoparticle diameter is about 80 μm. In certain embodiments, the average nanoparticle diameter is about 90 μm. In further embodiments, the average nanoparticle diameter is about 100 μm.

In certain embodiments, the method further comprises removal of the nanoparticle fillers. In further embodiments, the removal of the nanoparticle fillers comprises melting, evaporating, subliming, or dissolving the filler nanoparticles. In yet further embodiments, dissolving the nanoparticle fillers comprises acid or base dissolution. In still further embodiments, dissolving the nanoparticle fillers comprises acid dissolution.

In certain embodiments, the cross-linker comprises a combination of DVS and a metal oxide or metal hydrate. In further embodiments, the ratio of the DVS to the metal oxide or metal hydrate is about 1:99 to about 99:1. In yet further embodiments, the ratio of the DVS to the metal oxide or metal hydrate is about 1:99. In still further embodiments, the ratio of the DVS to the metal oxide or metal hydrate is about 1:90. In certain embodiments, the ratio of the DVS to the metal oxide or metal hydrate is about 1:80. In further embodiments, the ratio of the DVS to the metal oxide or metal hydrate is about 1:70. In yet further embodiments, the ratio of the DVS to the metal oxide or metal hydrate is about 1:60. In still further embodiments, the ratio of the DVS to the metal oxide or metal hydrate is about 1:50. In certain embodiments, the ratio of the DVS to the metal oxide or metal hydrate is about 1:40. In further embodiments, the ratio of the DVS to the metal oxide or metal hydrate is about 1:30. In yet further embodiments, the ratio of the DVS to the metal oxide or metal hydrate is about 1:20. In still further embodiments, the ratio of the DVS to the metal oxide or metal hydrate is about 1:10.

In certain embodiments, the ratio of the DVS to the metal oxide or metal hydrate is about 1:1. In further embodiments, the ratio of the DVS to the metal oxide or metal hydrate is about 10:1. In yet further embodiments, the ratio of the DVS to the metal oxide or metal hydrate is about 20:1. In still further embodiments, the ratio of the DVS to the metal oxide or metal hydrate is about 30:1. In certain embodiments, the ratio of the DVS to the metal oxide or metal hydrate is about 40:1. In further embodiments, the ratio of the DVS to the metal oxide or metal hydrate is about 50:1. In yet further embodiments, the ratio of the DVS to the metal oxide or metal hydrate is about 60:1. In still further embodiments, the ratio of the DVS to the metal oxide or metal hydrate is about 70:1. In certain embodiments, the ratio of the DVS to the metal oxide or metal hydrate is about 80:1. In further embodiments, the ratio of the DVS to the metal oxide or metal hydrate is about 90:1. In yet further embodiments, the ratio of the DVS to the metal oxide or metal hydrate is about 99:1.

In certain embodiments, the average pore diameter is about 1 nm to about 500 μm. In preferred embodiments, the average pore diameter is about 5 μm to about 500 μm. In yet further embodiments, the average pore diameter is about 5 μm. In still further embodiments, the average pore diameter is about 10 μm. In certain embodiments, the average pore diameter is about 50 μm. In further embodiments, the average pore diameter is about 100 μm. In yet further embodiments, the average pore diameter is about 200 μm. In still further embodiments, the average pore diameter is about 300 μm. In certain embodiments, the average pore diameter is about 400 μm. In further embodiments, the average pore diameter is about 500 μm.

In certain embodiments, the induction of porosity and cross-linking further comprises drying. In further embodiments, the drying is air drying or freeze-drying.

In certain embodiments, the induction of porosity and cross-linking further comprises dry annealing.

### Porous Polymeric Materials

In an aspect, provided herein are porous polymeric materials made by any of the methods disclosed herein. In certain embodiments, the polymeric material is a thin film, a sponge, a foam, a wafer, a sheet, a fiber, or a gel. In further embodiments, the gel is a hydrogel or a cryogel.

### EXAMPLES

In order that the invention described herein may be more fully understood, the following examples are set forth. The examples described in this application are offered to illustrate the compositions and methods provided herein and are not to be construed in any way as limiting their scope.

### Example 1: Synthesis of PEDOT:PSS Solution

Pure PEDOT:PSS (150 kDA) pellets were obtained from Sigma Millipore (Burlington, Mass.) and assumed as 100% by weight. PEDOT:PSS pellets were disbursed in varying volumes of water to obtain 1%, 2%, and 3% solutions (wt/v). Concentrations higher than 3% required additional agitation, heating, or extended lengths of time for polymer chain disentanglement for efficient disbursement to occur. Low concentrations still required 3-7 days for proper chain disentanglement. It should be noted that regardless of the concentration solutions were consistently viscous. Divinyl sulfone (DVS) was obtained from Aldrich (Burlington, Mass.) and used without further processing.

### Example 2: Synthesis of PEDOT:Polyanionic Polymer

PEDOT:polyanionic polymer solution was synthesized via oxidative polymerization. Briefly, 0.5 g of 3,4-Ethylenedioxythiophene (EDOT) monomer and a polyanionic polymer (0.5-5.0 g) were mixed with 1 g of Na2S2O8 (oxidant), at a ratio of 1:2 of EDOT:Na2S2O8, in 100 mL of DI water for 24 hours at room temperature. The solution was then centrifuged and supernatant removed. The precipitate was then mixed with an acetone:methanol mixture and centrifuged again and supernatant removed. The precipitate was then freeze-dried. The dried powder is the PEDOT:polyanionic polymer.

### Example 3: Synthesis of PEDOT:Polycationic Polymer

PEDOT:polycationic polymer solution was synthesized via oxidative polymerization. Briefly, 0.5 g of 3,4-Ethylenedioxythiophene (EDOT) monomer and a polycationic polymer (0.5-5.0 g) were mixed with lg of Na2S2O8 (oxidant), at a ratio of 1:2 of EDOT:Na2S2O8, in 100 mL of DI water for 24 hours at room temperature. The solution was then centrifuged and supernatant removed. The precipitate was then mixed with an acetone:methanol mixture and centrifuged again and supernatant removed. The precipitate was then freeze-dried. The dried powder is the PEDOT:polycationic polymer.

### Example 4: Synthesis of PEDOT:Polyacid Polymer

PEDOT:polyacid polymer solution was synthesized via oxidative polymerization. Briefly, 0.5 g of 3,4-Ethylenedioxythiophene (EDOT) monomer and a polyacid polymer (0.5-5.0 g) were mixed with 1 g of Na2S2O8 (oxidant), at a ratio of 1:2 of EDOT:Na2S2O8, in 100 mL of DI water for 24 hours at room temperature. The solution was then centrifuged and supernatant removed. The precipitate was then mixed with an acetone:methanol mixture and centrifuged again and supernatant removed. The precipitate was then freeze-dried. The dried powder is the PEDOT:polyacid polymer.

### Example 5: Synthesis of PEDOT:Polybasic Polymer

PEDOT:polybasic polymer solution was synthesized via oxidative polymerization. Briefly, 0.5 g of 3,4-Ethylenedioxythiophene (EDOT) monomer and a polybasic polymer (0.5-5.0 g) were mixed with 1 g of Na2S2O8 (oxidant), at a ratio of 1:2 of EDOT:Na2S2O8, in 100 mL of DI water for 24 hours at room temperature. The solution was then centrifuged and supernatant removed. The precipitate was then mixed with an acetone:methanol mixture and centrifuged again and supernatant removed. The precipitate was then freeze-dried. The dried powder is the PEDOT:polybasic polymer.

### Example 6: Synthesis of PEDOT:Amphoteric Polymer

PEDOT:amphoteric polymer solution was synthesized via oxidative polymerization. Briefly, 0.5 g of 3,4-Ethylenedioxythiophene (EDOT) monomer and an amphoteric polymer (0.5-5.0 g) were mixed with 1 g of Na2S2O8 (oxidant), at a ratio of 1:2 of EDOT:Na2S2O8, in 100 mL of DI water for 24 hours at room temperature. The solution was then centrifuged and supernatant removed. The precipitate was then mixed with an acetone:methanol mixture and centrifuged again and supernatant removed. The precipitate was then freeze-dried. The dried powder is the PEDOT:amphoteric polymer.

### Example 7: Synthesis of PEDOT:Biopolymer

PEDOT:biopolymer polymer solution was synthesized via oxidative polymerization. Briefly, 0.5 g of 3,4-Ethylenedioxythiophene (EDOT) monomer and a biopolymer polymer (0.5-5.0 g) were mixed with 1 g of Na2S2O8 (oxidant), at a ratio of 1:2 of EDOT:Na2S2O8, in 100 mL of DI water for 24 hours at room temperature. The solution was then centrifuged and supernatant removed. The precipitate was then mixed with an acetone:methanol mixture and centrifuged again and supernatant removed. The precipitate was then freeze-dried. The dried powder is the PEDOT:biopolymer polymer.

### Example 8: Synthesis of PEDOT:Polysaccharide

PEDOT:polysaccharide polymer solution was synthesized via oxidative polymerization. Briefly, 0.5 g of 3,4-Ethylenedioxythiophene (EDOT) monomer and a polysaccharide (0.5-5.0 g) were mixed with 1 g of Na2S2O8 (oxidant), at a ratio of 1:2 of EDOT:Na2S2O8, in 100 mL of DI water for 24 hours at room temperature. The solution was then centrifuged and supernatant removed. The precipitate was then mixed with an acetone:methanol mixture and centrifuged again and supernatant removed. The precipitate was then freeze-dried. The dried powder is the PEDOT:polysaccaride polymer.

### Example 9: Synthesis of PEDOT:Polyanionic-DVS Polymer

PEDOT:polyanionic-DVS polymer is fabricated by mixing PEDOT:polyanionic polymer powder in 97 uL of water with 3 uL of DVS. The PEDOT:polyanionic-DVS mixture was used immediately, as is, or in conjunction with a pore-inducing technique.

### Example 10: Synthesis of PEDOT:Polycationic-DVS Polymer

PEDOT:polycationic-DVS polymer is fabricated by mixing PEDOT:polycationic polymer powder in 97 uL of water with 3 uL of DVS. The PEDOT:polycationic-DVS mixture was used immediately, as is, or in conjunction with a pore-inducing technique.

### Example 11: Synthesis of PEDOT:Polyacid-DVS Polymer

PEDOT:polyacid-DVS polymer is fabricated by mixing PEDOT:polyacid polymer powder in 97 uL of water with 3 uL of DVS. The PEDOT:polyacid-DVS mixture was used immediately, as is, or in conjunction with a pore-inducing technique.

### Example 12: Synthesis of PEDOT:Polyanionic-DVS Polymer

PEDOT:polybasic-DVS polymer is fabricated by mixing PEDOT:polybasic polymer powder in 97 uL of water with 3 uL of DVS. The PEDOT:polybasic-DVS mixture was used immediately, as is, or in conjunction with a pore-inducing technique.

### Example 13: Synthesis of PEDOT:Polyamphoteric-DVS Polymer

PEDOT:polyamphoteric-DVS polymer is fabricated by mixing PEDOT:polyamphoteric polymer powder in 97 uL of water with 3 uL of DVS. The PEDOT:polyamphoteric-DVS mixture was used immediately, as is, or in conjunction with a pore-inducing technique.

### Example 14: Synthesis of PEDOT:Polybiopolymer-DVS Polymer

PEDOT:polybiopolymer-DVS polymer is fabricated by mixing PEDOT:polybiopolymer polymer powder in 97 uL of water with 3 uL of DVS. The PEDOT:polybiopolymer-DVS mixture was used immediately, as is, or in conjunction with a pore-inducing technique.

### Example 15: Synthesis of PEDOT:Polysaccharide-DVS Polymer

PEDOT:polysaccharide -DVS polymer is fabricated by mixing PEDOT:polysaccharide polymer powder in 97 uL of water with 3 uL of DVS. The PEDOT: polysaccharide-DVS mixture was used immediately, as is, or in conjunction with a pore-inducing technique.

### Example 16: Fabrication of PEDOT:PSS-DVS Films

100 μL of PEDOT:PSS solutions at varying concentrations were added to 3% of DVS (v/v). Films were then air dried until all the water evaporated. Hot plate heating (50° C.) can be additionally used to accelerate evaporation of water as well as ethanol, or other alcohol or highly volatile solution.

### Example 17: Fabrication of PEDOT:PSS-DVS Porous Structures

By heating the hot plate to a higher temperature (125° C.) PEDOT:PSS films can be annealed and generate porous microstructure by re-swelling. This can be further tuned with and without hot plate annealing. The novelty herein, is such that porous microstructure can be created using three techniques and be further enhanced using hot plate annealing, but is not necessary.

### Example 18: Sub-Freezing Microstructures

Porous microstructures within PEDOT:PSS have been previously investigated using liquid nitrogen or −80° C. However, technique 2 utilizes ranges of temperatures from 0° C. (household freezer temperatures) to −80° C. with varying pore sizes based on temperature. By varying temperature, pore size can be finely controlled. Specifically, PEDOT:PSS solution and DVS were vortexed at 4° C. and a droplet was placed onto a Teflon plate. The plate was immediately placed into a freezer. After 16 hours, the PEDOT:PSS was removed from freezing and the water was allowed to evaporate. Alternatively, samples were freeze-dried. It was noted that freeze-dried and air-dried samples retained the same porous structure. Imaging, however, was easier when samples were freeze-dried as samples retained rigidity better. Upon air-drying samples collapsed into a film. However, submerging in water caused the film to swell and recall porous shape memory. Samples underwent further processing by dry-annealing as previously done.

### Example 19: Phase Separation Microstructure

Porous microstructure within PEDOT:PSS can also be attained using phase separation using a solvent-nonsolvent combination. Specifically, varying ratios (0:100, 3:97, 10:90, 25:75, 50:50, 75:25, 90:10, 97:3, 100:0) of solvent (water)—non-solvent (toluene, y-butyrolactone, chloroform, benzene, xylene, ionic liquids) pairs were utilized in which PEDOT:PSS was diluted to 1-3% (wt/v), to which 3% (v/v) DVS was then added prior to droplet casting at room temperature. A surfactant, such as Triton X, can optionally be added to the non-solvent. PEDOT:PSS-DVS was then allowed to crosslink for 60 minutes. Toluene and y-butyrolactone were washed away in water, leaving the porous PEDOT:PSS-DVS microstructures. Pore size was controlled by varying ratio of solvent to non-solvent and by mixing speed (Rotations Per Minutes: RPM). By using an emulsifier and high mixing speeds, nanoporous structures were generated. Course mixing (i.e. vortex) resulted in macroporous pore structures. Chloroform, benzene, xylene, and ionic liquids must be more carefully removed as they are toxic.

### Example 20: Alternate Procedure for Phase Separation Microstructure

Porous microstructure within PEDOT:PSS can also be attained using phase separation using a solvent-nonsolvent combination. Specifically, varying ratios (0:100, 3:97, 10:90, 25:75, 50:50, 75:25, 90:10, 97:3, 100:0) of solvent (water)—non-solvent (petroleum oil, organic oil, vitamin E, or water immiscible ionic liquids) pairs were utilized in which PEDOT:PSS was diluted to 1-3% (wt/v), to which 3% (v/v) DVS was then added prior to droplet casting at room temperature. A surfactant, such as Triton X, can optionally be added to the non-solvent. PEDOT:PSS-DVS was then allowed to crosslink for 60 minutes. Oils or ionic liquids were washed away in hexane, leaving the porous PEDOT:PSS-DVS microstructures. Pore size was controlled by varying ratio of solvent to non-solvent and by mixing speed (Rotations Per Minutes: RPM). By using an emulsifier and high mixing speeds, nanoporous structures were generated. Course mixing (i.e. vortex) resulted in macroporous pore structures.

### Example 21: Phase Inversion Foaming

Porous microstructures within PEDOT:PSS were also attained using foaming. Specifically, by dissolving PEDOT:PSS in camphene or phenol, which are solid at room temperature, a porous structure was created upon solvent evaporation. PEDOT:PSS at varying concentrations (wt%) were dissolved in camphene or phenol at melting temperature. The resulting solution was allowed to cool to RT and solidify. This solution was stored for further use. A droplet of DVS was then placed upon a cut block portion of the bulk, and solvent was allowed to evaporate due to its low sublimation temperature. The DVS migrated downward into the PEDOT:PSS matrix as the solid solvent left the system. Subsequently, a porous polymer was retained. Ionic liquids, similarly, are solid at room temperature and PEDOT:PSS can be dissolved in one or multiple ionic liquids to obtain various porosity and microstructure.

### Example 22: Filler/Nanoparticle Loading

Porous microstructures of PEDOT:PSS were obtained using varying sized nanoparticles. Example: PEDOT:PSS was dissolved in water to form a 1-3% (wt/v) solution. The solution was then filled with polyethylene glycol nanoparticles (PEG of diameter 10 μm). The resulting nanoparticle solution block was cast into a Teflon® mold and annealed. Alternatively, the nanoparticle solution was mixed with 3% (v/v) DVS and cast into a Teflon® mold, after 24 hours of room temperature incubation, or higher temperature incubation for faster results, the resulting block was submerged into a chloroform bath in which the PEG was dissolved. Similarly, foaming agent nanoparticles (ex. camphene) can be used and then allowed to sublime at room temperature.

### Example 23: Metal Cross-Linkers

Silver, Gold, Aluminum, Zinc, Copper, Magnesium, Calcium, Lithium, Iron, Chromium, and Titanium oxides and hydrates can also be utilized to induce porosity and crosslink PEDOT:PSS at the same time. Furthermore, combining this technique with annealing or sub-freezing can also give further pore size control. Specifically, PEDOT:PSS solution, as previously outlined, can be combined with equal molar ratios of metal oxide/hydrate to react all the metal binding sites. The mixed solution can then be cast into a Teflon® mold for crosslinking and final substrate formation. Unreacted portions can then be washed away by submerging the scaffold in water.

### Example 24: Chemical Characterization of PEDOT:PSS-DVS

IR spectra were collected by a Thermo Fisher Nikolet i150 ATR-FTIR spectrometer. PEDOT:PSS solution was placed onto the ATR crystal and then DVS was added at the appropriate concentrations. Single beam IR spectra were taken for up to 40 minutes, with 30 s intervals using a custom Visual Basic script for running time-lapse experiments. To remove the presence of water, a spectrum of water was obtained and subtracted from the obtained PEDOT:PSS spectra. The resulting spectra were analyzed using OMNIC software, which was provided with the spectrometer. The spectra taken were further processed using the Peak Resolve tool to obtain greater granularity and resolution of each obtained spectra, within OMNIC. Peaks at 712 and 780 represent the vinyl groups of the DVS, whereas the presence of a peak at 752 is an indication of a C—C ethyl which occurs during the vinyl degradation from a double bond to a single bond. Additionally, a peak at 826 and 995 indicate the vibrational frequencies of C—O which occur during the DVS and PSS (from the PEDOT:PSS) bond formation.

### Example 25: Sprayability

Post-technique optimization and chemical characterization, spray deployment is the key uniqueness of this project. PEDOT:PSS-DVS can be crosslinked with porous structures post-spray. Specifically, for sub-freezing spraying, PEDOT:PSS and DVS which has been mixed at RT or cooler, or applied with a dual spray system, were immediately placed into a freezer (−20° C.) and allowed to crosslink. Similarly, for foaming, a heated cartridge can be sprayed onto a surface followed by a spray of DVS—no mixing is required for this method. Additionally, for foaming, a dual spray system in which the foaming agent (camphene or phenol) is heated, is mixed within the nozzle prior to spray and allowed to cool to RT where it will solidify. Additionally, for phase separation solutions, a premixed solution which has been vortexed for the users porous requirements, can be sprayed directly with a dual spray system in which PEDOT:PSS (in water), and a non-solvent is mixed with DVS in the nozzle upon spray ejection.

### INCORPORATION BY REFERENCE

All publications and patents mentioned herein are hereby incorporated by reference in their entirety as if each individual publication or patent was specifically and individually indicated to be incorporated by reference. In case of conflict, the present application, including any definitions herein, will control.

### EQUIVALENTS

While specific embodiments of the subject invention have been discussed, the above specification is illustrative and not restrictive. Many variations of the invention will become apparent to those skilled in the art upon review of this specification and the claims below. The full scope of the invention should be determined by reference to the claims, along with their full scope of equivalents, and the specification, along with such variations.

1. A method of making a cross-linked porous polymeric material, the method comprising:
inducing porosity and cross-linking in a mixture comprising poly(3,4-ethylenedioxythiophene) (PEDOT), an additional polymer, a cross-linker, and at least one solvent to form a cross-linked porous polymeric material;
wherein:
the cross-linked porous polymeric material comprises a plurality of pores having an average pore diameter;
the additional polymer is an acidic polymer, a basic polymer, a polyanionic polymer, a polycationic polymer, a sulfonate-containing polymer, a biopolymer, or an amphoteric polymer; and
the cross-linker is a molecule with two or more vinyl functional groups, a metal oxide, a metal hydrate, or a combination thereof.

2. (canceled)

3. The method of claim 1, wherein the additional polymer is poly(styrenesulfonate) (PSS).

4. The method of claim 1, wherein the cross-linker is a molecule with two or more vinyl functional groups.

5. (canceled)

6. The method of claim 4, wherein the molecule with two or more vinyl functional groups is divinyl sulfone (DVS).

7.-11. (canceled)

12. The method of claim 1, wherein the at least one solvent is water.

13. The method of claim 12, wherein the concentration of the PEDOT and the additional polymer in the at least one solvent is about 0.5% w/w to about 10% w/w.

14. The method of claim 1, wherein the concentration of the cross-linker in the at least one solvent is about 0.01% to about 90% v/v.

15. The method of claim 1, wherein prior to the induction of porosity and cross-linking, the method further comprises the step of:
admixing the PEDOT and the additional polymer with a first solvent to form a dispersed polymer mixture.

16. (canceled)

17. The method of claim 15, wherein the first solvent is water.

18.-19. (canceled)

20. The method of claim 15, wherein following the admixing and prior to the induction of porosity and cross-linking, the method further comprises the step of:
combining the dispersed polymer mixture and the cross-linker or a cross-linker solution to form a combined mixture; wherein the cross-linker solution comprises the cross-linker and a second solvent.

21. (canceled)

22. The method of claim 20, wherein the second solvent is water.

23. The method of claim 20, wherein following the combining and prior to the induction of porosity and cross-linking, the method further comprises the step of:
applying the combined mixture to a surface or vessel.

24. (canceled)

25. The method of claim 1, wherein the induction of porosity and cross-linking comprises thermal annealing.

26. (canceled)

27. The method of claim 20, wherein the combined mixture further comprises a non-solvent.

28.-29. (canceled)

30. The method of claim 27, wherein the ratio of the first and/or second solvent to the non-solvent is about 1:100 to about 100:1.

31.-33. (canceled)

34. The method of claim 27, wherein the non-solvent further comprises a surfactant.

35. The method of claim 34, wherein the surfactant is polyethylene glycol p-(1,1,3,3-tetramethylbutyl)-phenyl ether.

36.-37. (canceled)

38. The method of claim 20, wherein the induction of porosity and cross-linking comprises cooling at a cooling rate the combined mixture to a sub-freezing temperature that is below the freezing point of the first and/or second solvent.

39.-42. (canceled)

43. The method of claim 20, wherein the combined mixture further comprises nanoparticle fillers having an average nanoparticle diameter of about 1 nm to about 100 μm; and the induction of porosity and cross-linking further comprises removal of the nanoparticle fillers.

44.-51. (canceled)

52. The method of claim 20, wherein the combined mixture further comprises a third solvent; the third solvent has a melting point which is higher than about 25° C.; and the induction of porosity and cross-linking further comprises foaming the combined mixture to form a foamed mixture.

53. (canceled)

54. The method of claim 52, wherein the third solvent is selected from the group consisting of camphene, phenol, naphthalene, camphor, 18-crown-6, imidazole, and an alcohol, such as tertiary butanol, isopropyl alcohol, ethanol, or n-propanol.

55.-57. (canceled)

58. The method of claim 52, wherein the foamed mixture further comprises nanoparticle fillers having an average nanoparticle diameter of about 1 nm to about 100 μm.

59.-66. (canceled)

67. The method of claim 1, wherein the cross-linker comprises a combination of DVS and a metal oxide or metal hydrate; and the ratio of the DVS to the metal oxide or metal hydrate is about 1:99 to about 99:1.

68.-69. (canceled)

70. The method of claim 1 wherein the average pore diameter is about 5 μm to about 500 μm.

71. The method of claim 1, wherein the induction of porosity and cross-linking further comprises drying.

72. (canceled)

73. The method of claim 1, wherein the induction of porosity and cross-linking further comprises dry annealing.

74.-78. (canceled)
